(19) United States
(12) Patent Application Publication
(10) Pub. No.: US 2025/0287659 A1
(43) Pub. Date: Sep. 11, 2025

(54) SEMICONDUCTOR DEVICE AND METHOD FOR FABRICATING THE SAME

(71) Applicant: Samsung Electronics Co., Ltd., Suwon-si (KR)

(72) Inventors: Hyun Jun Lim, Suwon-si (KR); Min Seok Jo, Suwon-si (KR)

(21) Appl. No.: 18/828,245

(22) Filed: Sep. 9, 2024

(30) Foreign Application Priority Data
Mar. 6, 2024 (KR) 10-2024-0031779

(51) Int. Cl. H01L 29/06; H01L 29/417; H01L 29/423; H01L 29/66; H01L 29/775; H01L 29/786

(52) U.S. Cl. CPC H10D 62/121; H10D 30/014; H10D 30/43; H10D 30/6729; H10D 30/6735; H10D 30/6757; H10D 64/017

(57) ABSTRACT

A semiconductor device may include a lower interlayer insulating layer, an insulating pattern on the lower interlayer insulating layer, an active pattern on the lower interlayer insulating layer and spaced apart from the insulating pattern, a dummy active pattern on the active pattern, a field insulating layer on sidewalls of the insulating pattern, the active pattern, and the dummy active pattern, first nanosheets on the insulating pattern, second nanosheets on the dummy active pattern, a gate electrode on the insulating pattern and the dummy active pattern and on the first and second nanosheets, a first source/drain region on a side of the gate electrode and on the insulating pattern, a second source/drain region on the side of the gate electrode and on the dummy active pattern, a bottom source/drain contact electrically connected to the first source/drain region, and an upper source/drain contact electrically connected to the second source/drain region.

### CROSS-REFERENCE TO RELATED APPLICATIONS

This application claims priority from Korean Patent Application No. 10-2024-0031779 filed on Mar. 6, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to a semiconductor device and a method of fabricating the same, and more particularly, to a semiconductor device including, for example, a MBCFET™ (Multi-Bridge Channel Field Effect Transistor) and a method of fabricating the same.

As one of the scaling techniques to increase the density of integrated circuit devices, multi-gate transistors have been proposed, in which a fin-shaped or nanowire-shaped silicon body is formed on a substrate and gates are formed on the surface of the silicon body.

These multi-gate transistors utilize a three-dimensional channel and are easy to scale. Additionally, current control capability may be improved without increasing the gate length of the multi-gate transistor. Furthermore, the SCE (short channel effect), in which the potential of the channel region is affected by the drain voltage, may be effectively suppressed.

### SUMMARY OF THE INVENTION

Aspects of the present disclosure provide a semiconductor device and a method of fabricating a semiconductor device that allow for structural stability of a source/drain region to which a bottom source/drain contact is connected.

Aspects of the present disclosure are not limited to those mentioned above and other aspects which are not mentioned above will be clearly understood by those skilled in the art from the description below.

According to some embodiments of the present disclosure, a semiconductor device may include a lower interlayer insulating layer, an insulating pattern extending in a first horizontal direction on an upper surface of the lower interlayer insulating layer, an active pattern extending in the first horizontal direction on the upper surface of the lower interlayer insulating layer, the active pattern spaced apart from the insulating pattern in a second horizontal direction different from the first horizontal direction, the active pattern including a material different from a material of the insulating pattern, a dummy active pattern extending in the first horizontal direction on an upper surface of the active pattern and in contact with the upper surface of the active pattern, a field insulating layer on the upper surface of the lower interlayer insulating layer and on sidewalls of the insulating pattern, the active pattern, and the dummy active pattern, a first plurality of nanosheets stacked and spaced apart from each other in a vertical direction on an upper surface of the insulating pattern, a second plurality of nanosheets stacked and spaced apart from each other in the vertical direction on an upper surface of the dummy active pattern, a gate electrode extending in the second horizontal direction on the insulating pattern and the dummy active pattern, the gate electrode at least partially surrounding each of the first and second plurality of nanosheets, a first source/drain region on a side of the gate electrode and on the insulating pattern, the first source/drain region being in contact with the insulating pattern, a second source/drain region on the side of the gate electrode and on the dummy active pattern, the second source/drain region being in contact with the dummy active pattern, a bottom source/drain contact extending in the lower interlayer insulating layer and the insulating pattern in the vertical direction, the bottom source/drain contact electrically connected to the first source/drain region, and an upper source/drain contact on the second source/drain region, the upper source/drain contact electrically connected to the second source/drain region.

According to some embodiments of the present disclosure, a semiconductor device may include a lower interlayer insulating layer, an insulating pattern extending in a first horizontal direction on an upper surface of the lower interlayer insulating layer, an active pattern extending in the first horizontal direction on the upper surface of the lower interlayer insulating layer, the active pattern spaced apart from the insulating pattern in a second horizontal direction different from the first horizontal direction, the active pattern including a material different from a material of the insulating pattern, a dummy active pattern extending in the first horizontal direction on an upper surface of the active pattern and in contact with the upper surface of the active pattern, the dummy active pattern including silicon germanium (SiGe), a field insulating layer on the upper surface of the lower interlayer insulating layer and on sidewalls of the insulating pattern, the active pattern, and the dummy active pattern, wherein an upper surface of the field insulating layer is higher in a vertical direction than an upper surface of the insulating pattern and an upper surface of the dummy active pattern, relative to the upper surface of the lower interlayer insulating layer, a gate electrode extending in the second horizontal direction on the insulating pattern and the dummy active pattern, a first source/drain region on a side of the gate electrode and on the insulating pattern, a second source/drain region on the side of the gate electrode and on the dummy active pattern, a bottom source/drain contact extending in the lower interlayer insulating layer and the insulating pattern in the vertical direction, the bottom source/drain contact electrically connected to the first source/drain region, and an upper source/drain contact on the second source/drain region, the upper source/drain contact electrically connected to the second source/drain region.

According to some embodiments of the present disclosure, a method of fabricating a semiconductor device may include forming a first semiconductor layer including silicon germanium (SiGe) on an upper surface of a substrate, alternately stacking second semiconductor layers including silicon (Si) and third semiconductor layers including silicon germanium (SiGe) on an upper surface of the first semiconductor layer, etching portions of the substrate and the first to third semiconductor layers to form first and second active patterns extending in a first horizontal direction on a lower surface of the first semiconductor layer, wherein the second active pattern is spaced apart from the first active pattern in a second horizontal direction different from the first horizontal direction, forming a field insulating layer on the substrate and on sidewalls of the first active pattern, the second active pattern, and the first semiconductor layer, forming a dummy gate extending in the second horizontal direction on an upper surface of the field insulating layer and on an upper surface of an uppermost one of the second semiconductor layers, forming a first source/drain region on a side of the dummy gate and on the first active pattern, and forming a second source/drain region on the side of the dummy gate and on the second active pattern, wherein a first portion of the first semiconductor layer in contact with a lower surface of the first source/drain region is defined as a first dummy active pattern, and wherein a second portion of the first semiconductor layer in contact with a lower surface of the second source/drain region is defined as a second dummy active pattern, etching the dummy gate and the third semiconductor layers to form a gate trench, forming a gate electrode in the gate trench, forming an upper source/drain contact on the second source/drain region and electrically connected to the second source/drain region, etching the substrate, forming a protective layer on a lower surface of the second active pattern, etching the first active pattern and the first dummy active pattern, forming an insulating pattern on the lower surface of the first source/drain region, the insulating pattern extending in the first horizontal direction, and forming a bottom source/drain contact extending in the insulating pattern in a vertical direction and electrically connected to the first source/drain region.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line D-D′ of FIG. 1;

FIGS. 6 to 41 are intermediate stage diagrams for explaining methods of fabricating semiconductor devices according to some embodiments of the present disclosure;

FIGS. 42 to 44 are cross-sectional views for explaining a semiconductor device according to some other embodiments of the present disclosure;

FIGS. 45 to 47 are cross-sectional views for explaining a semiconductor device according to some other embodiments of the present disclosure; and

FIGS. 48 and 49 are cross-sectional views for explaining a semiconductor device according to some other embodiments of the present disclosure.

### DETAILED DESCRIPTION

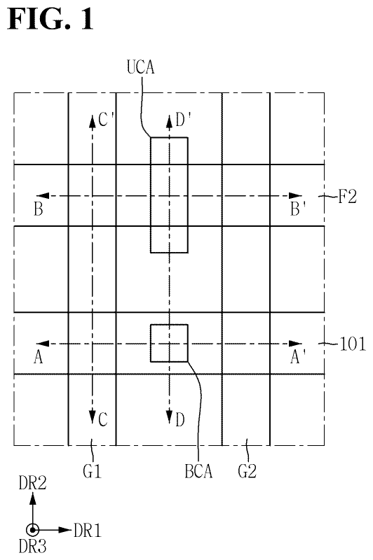

Hereinafter, a semiconductor device according to some embodiments of the present disclosure will be described with reference to FIGS. 1 to 5.

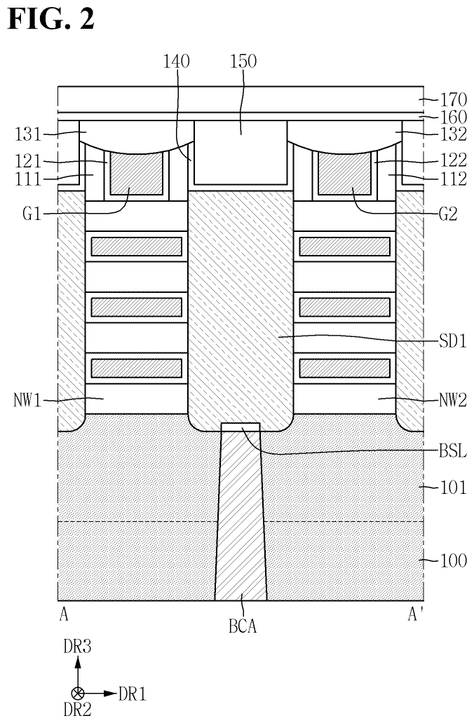

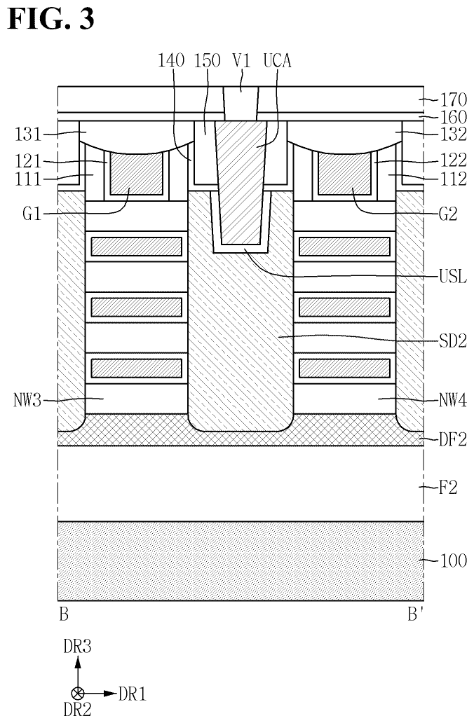

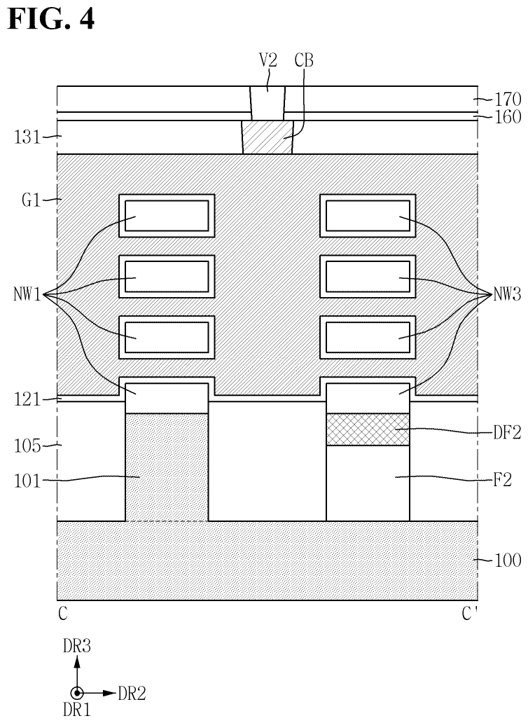

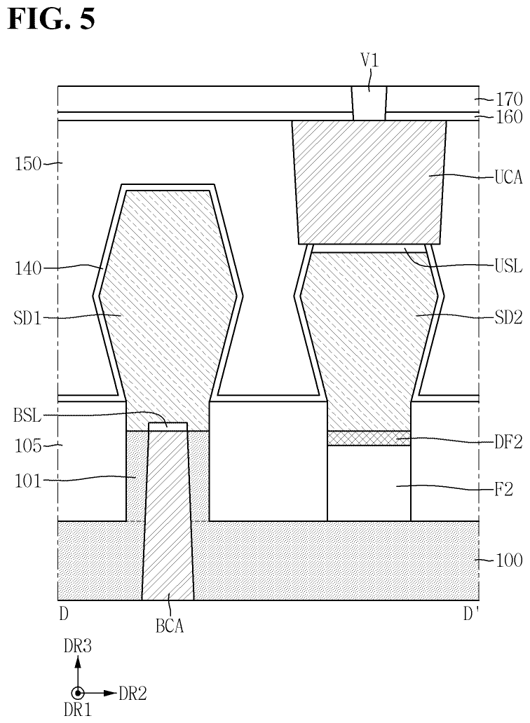

FIG. 1 is a layout diagram for explaining a semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line D-D′ of FIG. 1.

Referring to FIGS. 1 to 5, a semiconductor device according to some embodiments of the present disclosure includes a lower interlayer insulating layer 100, an insulating pattern 101, a second active pattern F2, a second dummy active pattern DF2, a field insulating layer 105, first to fourth plurality of nanosheets NW1 to NW4, first and second gate electrodes G1, G2, first and second gate spacers 111, 112, first and second gate insulating layers 121, 122, first and second capping patterns 131, 132, first and second source/drain regions SD1, SD2, a first etch stop layer 140, a first upper interlayer insulating layer 150, an upper source/drain contact UCA, a bottom source/drain contact BCA, an upper silicide layer USL, a bottom silicide layer BSL, a gate contact CB, a second etch stop layer 160, a second upper interlayer insulating layer 170, and first and second vias V1, V2.

The lower interlayer insulating layer 100 may include at least one of, for example, silicon oxide, silicon nitride, silicon oxynitride, or a low-k material. The low-k material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof, but the present disclosure is not limited thereto.

Hereinafter, each of the first horizontal direction DR1 and the second horizontal direction DR2 may be defined as directions parallel to the upper surface of the lower interlayer insulating layer 100. The second horizontal direction DR2 may be defined as a direction different from the first horizontal direction DR1. The vertical direction DR3 may be defined as a direction perpendicular to each of the first horizontal direction DR1 and the second horizontal direction DR2. In other words, the vertical direction DR3 may be defined as a direction perpendicular to the upper surface of the lower interlayer insulating layer 100.

The insulating pattern 101 may extend in the first horizontal direction DR1 on the upper surface of the lower interlayer insulating layer 100. The insulating pattern 101 may protrude from the upper surface of the lower interlayer insulating layer 100 in a vertical direction DR3. A lower surface of the insulating pattern 101 may be in contact with the upper surface of the lower interlayer insulating layer 100. The insulating pattern 101 may include an insulating material. For example, the insulating pattern 101 may include the same material as the lower interlayer insulating layer 100.

The second active pattern F2 may extend in a first horizontal direction DR1 on the upper surface of the lower interlayer insulating layer 100. The second active pattern F2 may be spaced apart from the insulating pattern 101 in the second horizontal direction DR2. The second active pattern F2 may protrude from the upper surface of the lower interlayer insulating layer 100 in the vertical direction DR3. The second active pattern F2 may be in contact with the upper surface of the lower interlayer insulating layer 100. For example, the uppermost surface of the second active pattern F2 may be formed lower than the uppermost surface of the insulating pattern 101 (e.g., when measured relative to the upper surface of the lower interlayer insulating layer 100 in the vertical direction DR3). For example, a lower surface of the second active pattern F2 may be formed on the same plane as (i.e., may be coplanar with) the lower surface of the insulating pattern 101. For example, the second active pattern F2 may overlap the insulating pattern 101 in the second horizontal direction DR2. As used herein, “an element A overlaps an element B in a direction X” (or similar language) means that there is at least one straight line that extends in the direction X and intersects both the elements A and B. The second active pattern F2 may include a material different from that of the lower interlayer insulating layer 100 and the insulating pattern 101, respectively. For example, the second active pattern F2 may include silicon (Si).

The second dummy active pattern DF2 may extend in the first horizontal direction DR1 on the upper surface of the second active pattern F2. A lower surface of the second dummy active pattern DF2 may be in contact with the upper surface of the second active pattern F2. For example, the profile of the two sidewalls in the second horizontal direction DR2 of the second dummy active pattern DF2 may be formed continuously with the profile of the two sidewalls in the second horizontal direction DR2 of the second active pattern F2. In other words, opposing sidewalls, in the second horizontal direction DR2, of the second dummy active pattern DF2 may be collinear along the vertical direction DR3 with opposing sidewalls, in the second horizontal direction DR2, of the second active pattern F2. For example, the uppermost surface of the second dummy active pattern DF2 may be formed on the same plane as the uppermost surface of the insulating pattern 101. For example, the second dummy active pattern DF2 may overlap the insulating pattern 101 in the second horizontal direction DR2. For example, the second dummy active pattern DF2 may include silicon germanium (SiGe).

The first plurality of nanosheets NW1 may be disposed on the upper surface of the insulating pattern 101. The first plurality of nanosheets NW1 may be disposed at the intersection of the insulating pattern 101 and a first gate electrode G1. The lower surface of the lowermost nanosheet of the first plurality of nanosheets NW1 may be in contact with the upper surface of the insulating pattern 101. The second plurality of nanosheets NW2 may be disposed on the upper surface of the insulating pattern 101. The second plurality of nanosheets NW2 may be disposed at an intersection of the insulating pattern 101 and a second gate electrode G2. The second plurality of nanosheets NW2 may be spaced apart from the first plurality of nanosheets NW1 in the first horizontal direction DR1. The lower surface of the lowermost nanosheet of the second plurality of nanosheets NW2 may be in contact with the upper surface of the insulating pattern 101.

The third plurality of nanosheets NW3 may be disposed on the upper surface of the second dummy active pattern DF2. The third plurality of nanosheets NW3 may be disposed at the intersection of the second dummy active pattern DF2 and the first gate electrode G1. The third plurality of nanosheets NW3 may be spaced apart from the first plurality of nanosheets NW1 in the second horizontal direction DR2. The lower surface of the lowermost nanosheet of the third plurality of nanosheets NW3 may be in contact with the upper surface of the second dummy active pattern DF2. The fourth plurality of nanosheets NW4 may be disposed on the upper surface of the second dummy active pattern DF2. The fourth plurality of nanosheets NW4 may be disposed at the intersection of the second dummy active pattern DF2 and the second gate electrode G2. The fourth plurality of nanosheets NW4 may be spaced apart from the third plurality of nanosheets NW3 in the first horizontal direction DR1. The fourth plurality of nanosheets NW4 may be spaced apart from the second plurality of nanosheets NW2 in the second horizontal direction DR2. The lower surface of the lowermost nanosheet of the fourth plurality of nanosheets NW4 may be in contact with the upper surface of the second dummy active pattern DF2.

Each of the first to fourth plurality of nanosheets (NW1 to NW4) may include a plurality of nanosheets stacked and spaced apart from each other in the vertical direction DR3. In FIGS. 2 to 4, each of the first to fourth plurality of nanosheets (NW1 to NW4) is shown as including four nanosheets stacked and spaced apart from each other in the vertical direction DR3, but this is for convenience of explanation and the present disclosure is not limited thereto. In some other embodiments, each of the first to fourth plurality of nanosheets (NW1 to NW4) may include three nanosheets spaced apart and stacked in the vertical direction DR3. In some other embodiments, each of the first to fourth plurality of nanosheets (NW1 to NW4) may include five or more nanosheets stacked and spaced apart from each other in the vertical direction DR3. For example, each of the first to fourth plurality of nanosheets (NW1 to NW4) may include silicon (Si). However, the present disclosure is not limited thereto. In some other embodiments, each of the first to fourth plurality of nanosheets (NW1 to NW4) may include silicon germanium (SiGe).

The field insulating layer 105 may be disposed on the upper surface of the lower interlayer insulating layer 100. The field insulating layer 105 may surround the sidewalls of each of the insulating pattern 101, the second active pattern F2, and the second dummy active pattern DF2. The field insulating layer 105 may be in contact with the sidewalls of each of the insulating pattern 101, the second active pattern F2, and the second dummy active pattern DF2. For example, the field insulating layer 105 may be in contact with the sidewalls (e.g., a lower portion of the sidewalls) of each of the first and third plurality of nanosheets NW1, NW3 in the second horizontal direction DR2. Although not shown, the field insulating layer 105 may be in contact with the sidewalls (e.g., a lower portion of the sidewalls) of each of the second and fourth plurality of nanosheets NW2, NW4 in the second horizontal direction DR2.

For example, the upper surface of the field insulating layer 105 may be formed higher than each of the upper surface of the insulating pattern 101 and the upper surface of the second dummy active pattern DF2 (e.g., when measured relative to the upper surface of the lower interlayer insulating layer 100 in the vertical direction DR3). For example, the upper surface of the field insulating layer 105 may be formed higher than each of the lower surface of the lowermost nanosheet of the first plurality of nanosheets NW1 and the lower surface of the lowermost nanosheet of the third plurality of nanosheets NW3 (e.g., when measured relative to the upper surface of the lower interlayer insulating layer 100 in the vertical direction DR3). Further, the upper surface of the field insulating layer 105 may be formed lower than each of the upper surface of the lowermost nanosheet of the first plurality of nanosheets NW1 and the upper surface of the lowermost nanosheet of the third plurality of nanosheets NW3 (e.g., when measured relative to the upper surface of the lower interlayer insulating layer 100 in the vertical direction DR3). Although not shown, the upper surface of the field insulating layer 105 may be formed higher than each of the lower surface of the lowermost nanosheet of the second plurality of nanosheets NW2 and the lower surface of the lowermost nanosheet of the fourth plurality of nanosheets NW4 (e.g., when measured relative to the upper surface of the lower interlayer insulating layer 100 in the vertical direction DR3). Further, the upper surface of the field insulating layer 105 may be formed lower than each of the upper surface of the lowermost nanosheet of the second plurality of nanosheets NW2 and the upper surface of the lowermost nanosheet of the fourth plurality of nanosheets NW4 (e.g., when measured relative to the upper surface of the lower interlayer insulating layer 100 in the vertical direction DR3). The field insulating layer 105 may include, for example, an oxide layer, a nitride layer, an oxynitride layer, or a combination thereof.

The first gate electrode G1 may extend in the second horizontal direction DR2 on the insulating pattern 101, the second dummy active pattern DF2, and the field insulating layer 105. The first gate electrode G1 may surround each of the first and third plurality of nanosheets NW1, NW3. It will be understood that “an element A surrounds an element B” (or similar language) as used herein means that the element A is at least partially around the element B but does not necessarily mean that the element A completely encloses the element B. The second gate electrode G2 may extend in the second horizontal direction DR2 on the insulating pattern 101, the second dummy active pattern DF2, and the field insulating layer 105. The second gate electrode G2 may surround each of the second and fourth plurality of nanosheets NW2, NW4. The second gate electrode G2 may be spaced apart from the first gate electrode G1 in the first horizontal direction DR1.

Each of the first and second gate electrodes G1, G2 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonnitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. Each of the first and second gate electrodes G1, G2 may include conductive metal oxides, conductive metal oxynitrides, and the like, and may also include an oxidized form of the above-described material.

The first gate spacer 111 may extend in the second horizontal direction DR2 along both (i.e., opposing) sidewalls of the first gate electrode G1 on the upper surface of the uppermost nanosheet of the first plurality of nanosheets NW1, the upper surface of the uppermost nanosheet of the third plurality of nanosheets NW3, and the upper surface of the field insulating layer 105. The second gate spacer 112 may extend in the second horizontal direction DR2 along both (i.e., opposing) sidewalls of the second gate electrode G2 on the upper surface of the uppermost nanosheet of the second plurality of nanosheets NW2, the upper surface of the uppermost nanosheet of the fourth plurality of nanosheets NW4, and the upper surface of the field insulating layer 105. Each of the first and second gate spacers 111, 112 may include at least one of, for example, silicon nitride (SiN), silicon oxynitride (SiON), silicon oxide (SiO2)), silicon carbonitride (SiOCN), silicon boron nitride (SiBN), silicon oxyboron nitride (SiOBN), silicon oxycarbide (SiOC), or combinations thereof. However, the present disclosure is not limited thereto.

The first source/drain region SD1 may be disposed on both (i.e., opposing) sides of each of the first and second gate electrodes G1, G2 on the insulating pattern 101. For example, the first source/drain region SD1 may include a plurality of first source/drain regions SD1 spaced apart from each other in the first horizontal direction DR1, with the first and second gate electrodes G1, G2 respectively between ones of the plurality of first source/drain regions SD1 (e.g., see FIG. 2). For example, the first source/drain region SD1 may be disposed between the first gate electrode G1 and the second gate electrode G2 on the insulating pattern 101. For example, the lower surface of the first source/drain region SD1 may be in contact with the insulating pattern 101. For example, the lower surface of the first source/drain region SD1 may be formed lower than each of the lower surface of the lowermost nanosheet of the first plurality of nanosheets NW1 and the lower surface of the lowermost nanosheet of the second plurality of nanosheets NW2 (e.g., when measured relative to the upper surface of the lower interlayer insulating layer 100 in the vertical direction DR3). For example, the lower surface of the first source/drain region SD1 may be formed lower than the upper surface of the field insulating layer 105 (e.g., when measured relative to the upper surface of the lower interlayer insulating layer 100 in the vertical direction DR3). For example, at least a portion of the sidewalls in the second horizontal direction DR2 of the first source/drain region SD1 may be in contact with the field insulating layer 105.

The second source/drain region SD2 may be disposed on both (i.e., opposing) sides each of the first and second gate electrodes G1, G2 on the second dummy active pattern DF2. For example, the second source/drain region SD2 may include a plurality of second source/drain regions SD2 spaced apart from each other in the first horizontal direction DR1, with the first and second gate electrodes G1, G2 respectively between ones of the plurality of second source/drain regions SD2 (e.g., see FIG. 3). For example, the second source/drain region SD2 may be disposed between the first gate electrode G1 and the second gate electrode G2 on the second dummy active pattern DF2. For example, the lower surface of the second source/drain region SD2 may be in contact with the second dummy active pattern DF2. For example, the lower surface of the second source/drain region SD2 may be formed lower than each of the lower surface of the lowermost nanosheet of the third plurality of nanosheets NW3 and the lower surface of the lowermost nanosheet of the fourth plurality of nanosheets NW4 (e.g., when measured relative to the upper surface of the lower interlayer insulating layer 100 in the vertical direction DR3). For example, the lower surface of the second source/drain region SD2 may be formed higher than the lower surface of the second dummy active pattern DF2 (e.g., when measured relative to the upper surface of the lower interlayer insulating layer 100 in the vertical direction DR3). For example, the lower surface of the second source/drain region SD2 may be formed lower than the upper surface of the field insulating layer 105 (e.g., when measured relative to the upper surface of the lower interlayer insulating layer 100 in the vertical direction DR3). For example, at least a portion of the sidewalls of the second source/drain region SD2 in the second horizontal direction DR2 may be in contact with the field insulating layer 105.

The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the third plurality of nanosheets NW3. The first gate insulating layer 121 may be disposed between the first gate electrode G1 and the first source/drain region SD1. The first gate insulating layer 121 may be disposed between the first gate electrode G1 and the second source/drain region SD2.

Although not specifically shown, the second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and the fourth plurality of nanosheets NW4. The second gate insulating layer 122 may be disposed between the second gate electrode G2 and the first source/drain region SD1. The second gate insulating layer 122 may be disposed between the second gate electrode G2 and the second source/drain region SD2.

For example, each of the first and second gate insulating layers 121, 122 may not be in contact with the insulating pattern 101 and the second dummy active pattern DF2, respectively. For example, each of the first and second gate insulating layers 121, 122 may be in contact with the first and second source/drain regions SD1, SD2, respectively. However, the present disclosure is not limited thereto. In some other embodiments, an internal spacer may be disposed between each of the first and second gate insulating layers 121, 122 and the first source/drain region SD1. Additionally, an internal spacer may be disposed between each of the first and second gate insulating layers 121, 122 and the second source/drain region SD2. The internal spacer may include at least one of, for example, silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof.

Each of the first and second gate insulating layers 121, 122 may include at least one of high-k material with a higher dielectric constant than silicon oxide, silicon oxynitride, silicon nitride, or silicon oxide. The high-k material may include, for example, at least one of hafnium oxide, hafnium silicon oxide, hafnium aluminum oxide, lanthanum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other embodiments may include a NC (Negative Capacitance) FET utilizing a negative capacitor. For example, each of the first and second gate insulating layers 121, 122 may include a ferroelectric material layer with ferroelectric properties and a paraelectric material layer with paraelectric properties.

The ferroelectric material layer may have a negative capacitance, while the paraelectric material layer may have a positive capacitance. For example, if two or more capacitors are connected in series and each capacitor has a positive capacitance, the overall capacitance will be decreased compared to the capacitance of each individual capacitor. On the other hand, if at least one of the capacitances of the two or more capacitors connected in series has a negative value, the overall capacitance may have a positive value and may be greater than the absolute value of each individual capacitance.

When a ferroelectric material layer with a negative capacitance and a paraelectric material layer with a positive capacitance are connected in series, the overall capacitance value of the ferroelectric material layer and the paraelectric material layer connected in series may be increased. By utilizing the increased overall capacitance value, the transistor including the ferroelectric material layer may have a subthreshold swing SS of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, or lead zirconium titanium oxide. For example, hafnium zirconium oxide may be a material in which zirconium (Zr) is doped into hafnium oxide. In another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). Depending on which ferroelectric material the ferroelectric material layer includes, the types of dopants included in the ferroelectric material layer may vary.

If the ferroelectric material layer includes hafnium oxide, the dopant included in the ferroelectric material layer may include, for example, at least one of gadolinium (Gd), silicon (Si), zirconium (Zr), aluminum (Al), or yttrium (Y).

If the dopant is aluminum (Al), the ferroelectric material layer may contain 3 to 8 at % (atomic %) of aluminum. Here, the ratio of the dopant may be the ratio of aluminum to the sum of hafnium and aluminum.

If the dopant is silicon (Si), the ferroelectric material layer may contain 2 to 10 at % of silicon. If the dopant is yttrium (Y), the ferroelectric material layer may contain 2 to 10 at % of yttrium. If the dopant is gadolinium (Gd), the ferroelectric material layer may contain 1 to 7 at % of gadolinium. If the dopant is zirconium (Zr), the ferroelectric material layer may contain 50 to 80 at % of zirconium.

The paraelectric material layer may have paraelectric properties. The paraelectric material layer may include, for example, at least one of silicon oxide or a metal oxide having a high dielectric constant. The metal oxide included in the paraelectric material layer may include, for example, at least one of hafnium oxide, zirconium oxide, or aluminum oxide, but is not limited thereto.

The ferroelectric material layer and the paraelectric material layer may include the same material. The ferroelectric material layer may have ferroelectric properties, while the paraelectric material layer may not have ferroelectric properties. For example, if the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness that exhibits ferroelectric properties, the thickness of the ferroelectric material layer may vary depending on the ferroelectric material.

As an example, each of the first and second gate insulating layers 121, 122 may include a single ferroelectric material layer. In another example, each of the first and second gate insulating layers 121, 122 may include a plurality of ferroelectric material layers spaced apart from each other. Each of the first and second gate insulating layers 121, 122 may have a laminated structure in which the plurality of ferroelectric material layers and the plurality of paraelectric material layers are alternately stacked.

The first etch stop layer 140 may be disposed on the sidewalls of each of the first and second gate spacers 111, 112 in the first horizontal direction DR1. The first etch stop layer 140 may be disposed on the upper surface of the field insulating layer 105. The first etch stop layer 140 may be disposed on the upper surface of each of the first and second source/drain regions SD1, SD2. The first etch stop layer 140 may be disposed on the sidewalls of each of the first and second source/drain regions SD1, SD2 in the second horizontal direction DR2. For example, the first etch stop layer 140 may be conformally formed. The first etch stop layer 140 may include at least one of, for example, aluminum oxide, aluminum nitride, hafnium oxide, zirconium oxide, silicon oxide, silicon nitride, silicon oxynitride, or a low-k material.

The first capping pattern 131 may extend in the second horizontal direction DR2 on each of the first gate spacer 111, the first gate insulating layer 121, and the first gate electrode G1. The second capping pattern 132 may extend in the second horizontal direction DR2 on each of the second gate spacer 112, the second gate insulating layer 122, and the second gate electrode G2. For example, the lower surface of each of the first and second capping patterns 131, 132 may be in contact with the first etch stop layer 140. However, the present disclosure is not limited thereto. In some other embodiments, the sidewalls of each of the first and second capping patterns 131, 132 may also be in contact with the first etch stop layer 140. Each of the first and second capping patterns 131, 132 may include at least one of, for example, silicon nitride (SiN), silicon oxynitride (SiON), silicon oxide (SiO2), silicon carbon nitride (SiCN), silicon oxycarbonitride (SiOCN), or combinations thereof. However, the present disclosure is not limited thereto.

The first upper interlayer insulating layer 150 may be disposed on the first etch stop layer 140. The first upper interlayer insulating layer 150 may be disposed on the sidewalls of each of the first and second capping patterns 131, 132. The first upper interlayer insulating layer 150 may be on (e.g., may cover) each of the first and second source/drain regions SD1, SD2 on the field insulating layer 105. For example, the upper surface of the first upper interlayer insulating layer 150 may be formed on the same plane as the upper surface of each of the first and second capping patterns 131, 132. The first upper interlayer insulating layer 150 may include at least one of, for example, silicon oxide, silicon nitride, silicon oxynitride, or a low-k material.

The upper source/drain contact UCA may be disposed between the first gate electrode G1 and the second gate electrode G2. The upper source/drain contact UCA may be disposed on the upper surface of the second source/drain region SD2. The upper source/drain contact UCA may extend into an interior of the second source/drain region SD2 by penetrating (i.e., extending in) the first upper interlayer insulating layer 150 and the first etch stop layer 140 in the vertical direction DR3. The upper source/drain contact UCA may be electrically connected to the second source/drain region SD2. In FIGS. 3 and 5, the upper source/drain contact UCA is illustrated as being formed as a single layer, but the present disclosure is not limited thereto. In some other embodiments, the upper source/drain contact UCA may be formed of multiple layers. For example, the upper surface of the upper source/drain contact UCA may be formed on the same plane as the upper surface of the first upper interlayer insulating layer 150. However, the present disclosure is not limited thereto. In some other embodiments, the upper surface of the upper source/drain contact UCA may be formed higher than the upper surface of the first upper interlayer insulating layer 150 (e.g., when measured relative to the upper surface of the lower interlayer insulating layer 100 in the vertical direction DR3). The upper source/drain contact UCA may include a conductive material.

The upper silicide layer USL may be disposed between the upper source/drain contact UCA and the second source/drain region SD2. The upper silicide layer USL may be disposed along the interface between the upper source/drain contact UCA and the second source/drain region SD2. The upper silicide layer USL may include, for example, a metal silicide material.

The gate contact CB may be disposed on the top of the first gate electrode G1. The gate contact CB may be connected to the first gate electrode G1 by penetrating the first capping pattern 131 in the vertical direction DR3. As used herein, “an element A connected to an element B” (or similar language) means that the element A is physically and/or electrically connected to the element B. In FIG. 4, the gate contact CB is illustrated as being formed as a single layer, but the present disclosure is not limited thereto. In some other embodiments, the gate contact CB may be formed of multiple layers. For example, the upper surface of the gate contact CB may be formed on the same plane as each of the upper surface of the upper source/drain contact UCA and the upper surface of the first upper interlayer insulating layer 150, but the present disclosure is not limited thereto. The gate contact CB may include a conductive material.

The bottom source/drain contact BCA may be disposed between the first gate electrode G1 and the second gate electrode G2 (e.g., when viewed in a plan view). The bottom source/drain contact BCA may be disposed at the bottom of the first source/drain region SD1. The bottom source/drain contact BCA may be electrically connected to the first source/drain region SD1 by penetrating the lower interlayer insulating layer 100 and the insulating pattern 101 in the vertical direction DR3. For example, the sidewalls of the bottom source/drain contact BCA may be surrounded by the lower interlayer insulating layer 100 and insulating pattern 101. For example, the sidewalls of the bottom source/drain contact BCA may be in contact with each of the lower interlayer insulating layer 100 and the insulating pattern 101.

For example, the width of the bottom source/drain contact BCA in the second horizontal direction DR2 may be smaller than the width of the insulating pattern 101 in the second horizontal direction DR2. For example, the upper surface of the bottom source/drain contact BCA may be formed on the same plane as the lower surface of the first source/drain region SD1, but the present disclosure is not limited thereto. For example, the bottom source/drain contact BCA may be formed as a single layer. However, the present disclosure is not limited thereto. In some other embodiments, the bottom source/drain contact BCA may be formed of multiple layers.

The bottom silicide layer BSL may be disposed between the bottom source/drain contact BCA and the first source/drain region SD1. The bottom silicide layer BSL may be disposed along the interface between the bottom source/drain contact BCA and the first source/drain region SD1. The bottom silicide layer BSL may include, for example, a metal silicide material.

The second etch stop layer 160 may be disposed on the upper surface of each of the upper source/drain contact UCA, the first and second capping patterns 131, 132, and the first interlayer insulating layer 150. In FIGS. 2 to 5, the second etch stop layer 160 is illustrated as being formed as a single layer, but the present disclosure is not limited thereto. In some other embodiments, the second etch stop layer 160 may be formed of multiple layers. The second etch stop layer 160 may include at least one of, for example, aluminum oxide, aluminum nitride, hafnium oxide, zirconium oxide, silicon oxide, silicon nitride, silicon oxynitride, or a low-k material. The second upper interlayer insulating layer 170 may be disposed on the second etch stop layer 160. The second upper interlayer insulating layer 170 may include at least one of, for example, silicon oxide, silicon nitride, silicon oxynitride, or a low-k material.

The first via V1 may be connected to the upper source/drain contact UCA by penetrating the second upper interlayer insulating layer 170 and the second etch stop layer 160 in the vertical direction DR3. The second via V2 may be connected to the gate contact CB by penetrating the second upper interlayer insulating layer 170 and the second etch stop layer 160 in the vertical direction DR3. In FIGS. 3 to 5, each of the first via V1 and the second via V2 is illustrated as being formed as a single layer, but the present disclosure is not limited thereto. In some other embodiments, each of the first via V1 and the second via V2 may be formed of multiple layers. Each of the first via V1 and the second via V2 may include a conductive material.

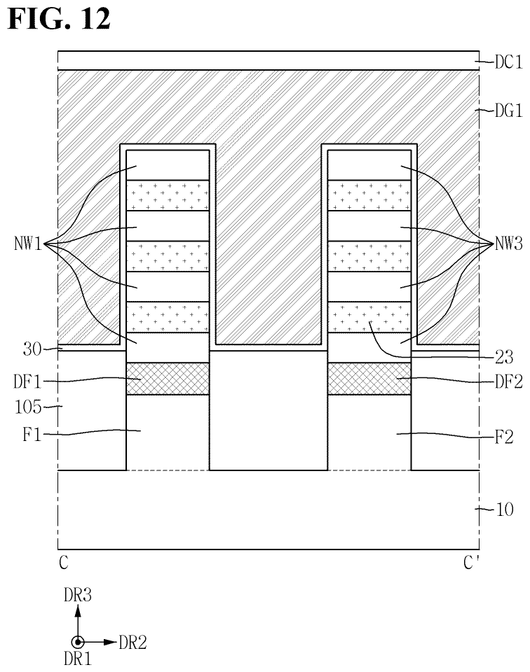

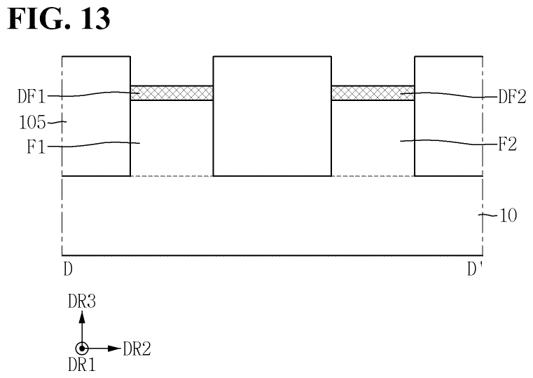

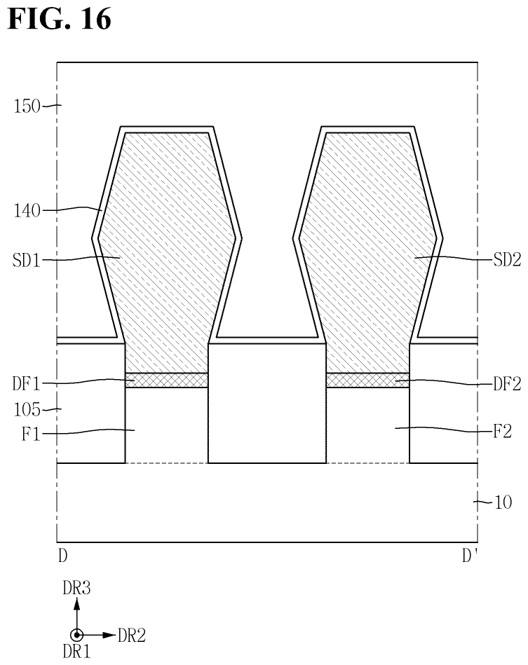

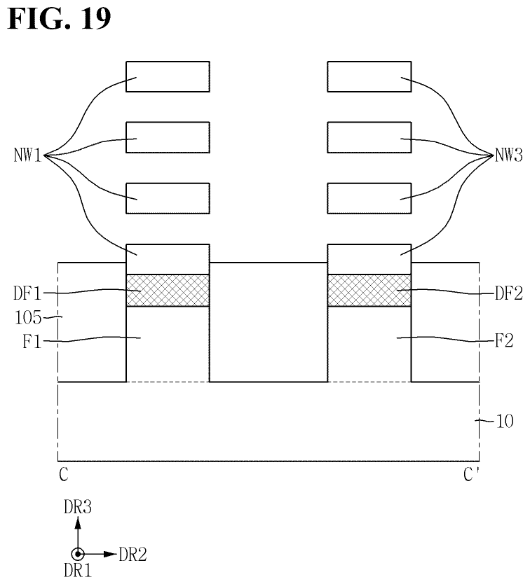

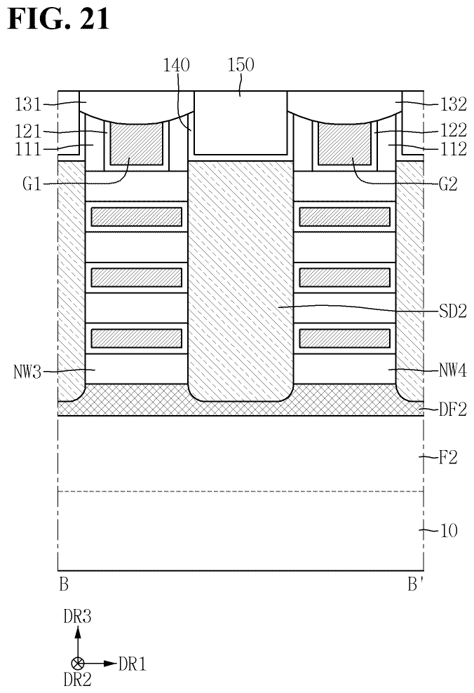

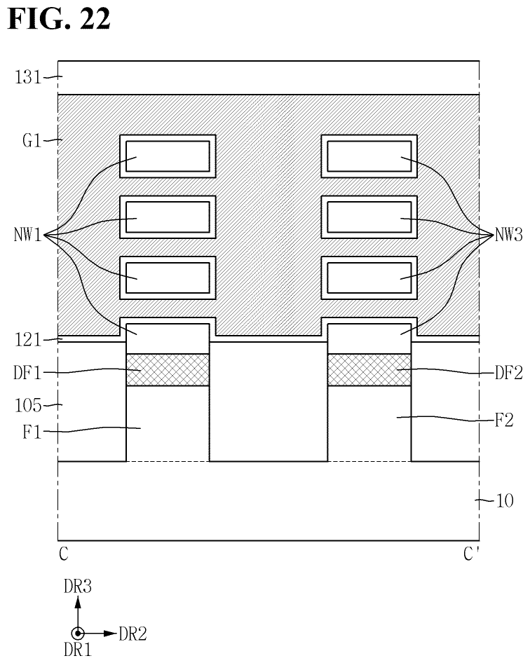

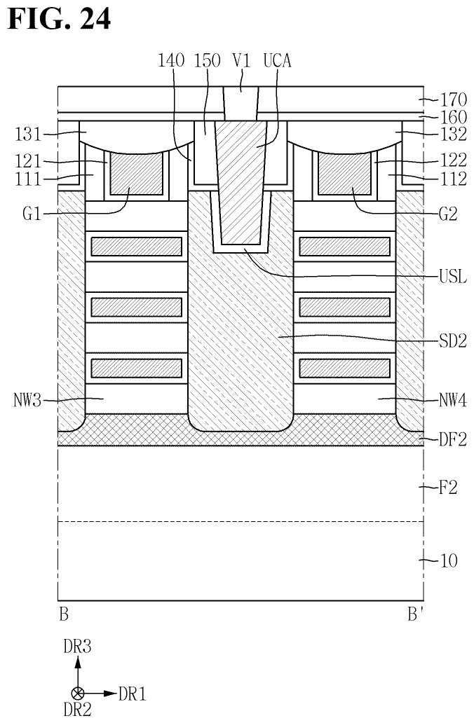

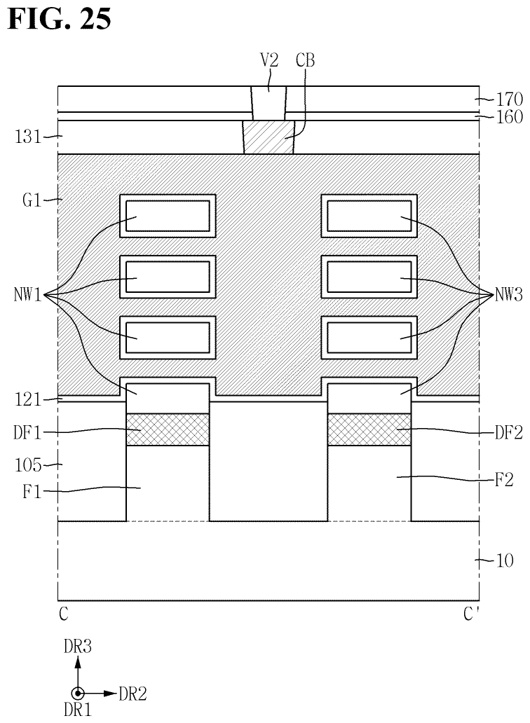

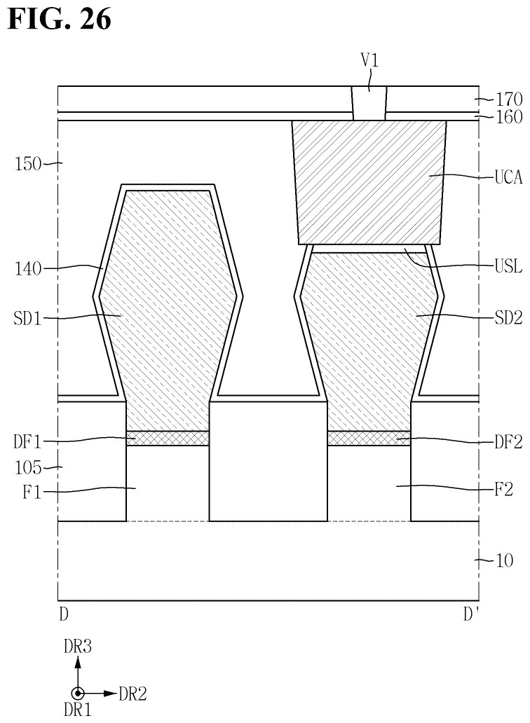

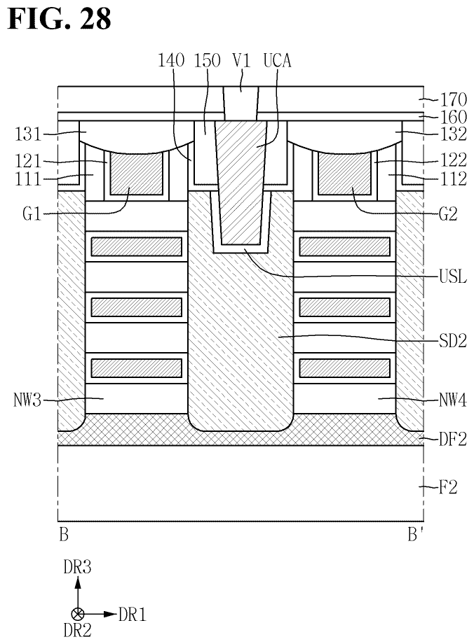

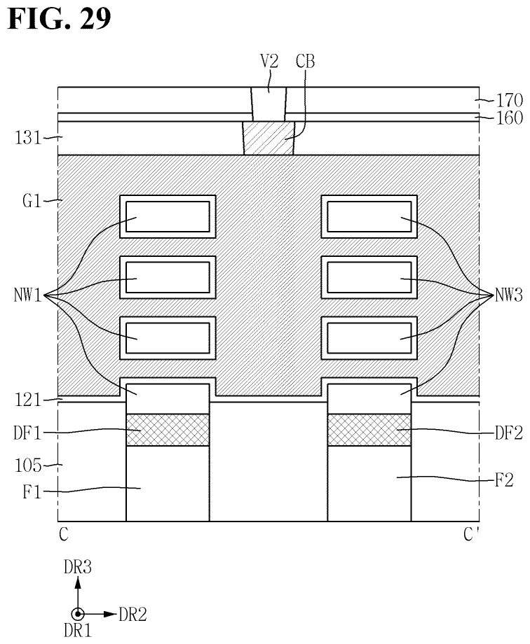

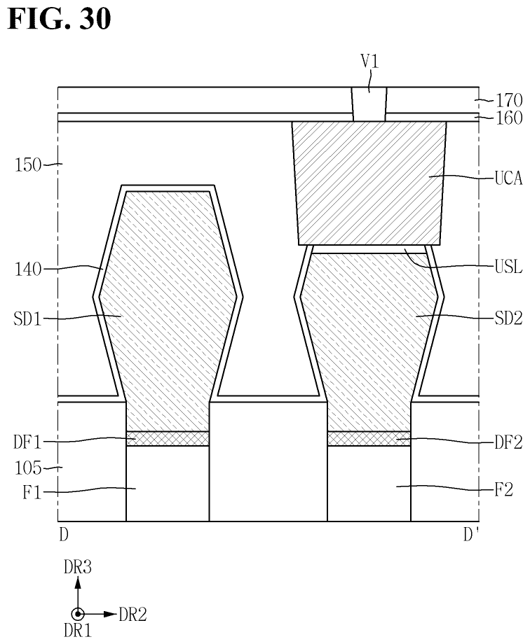

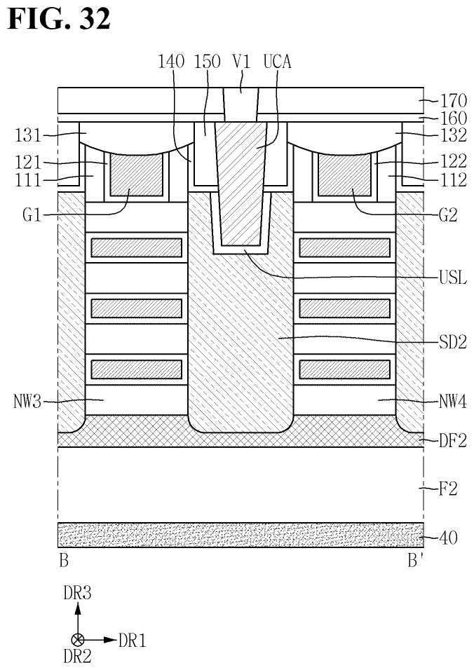

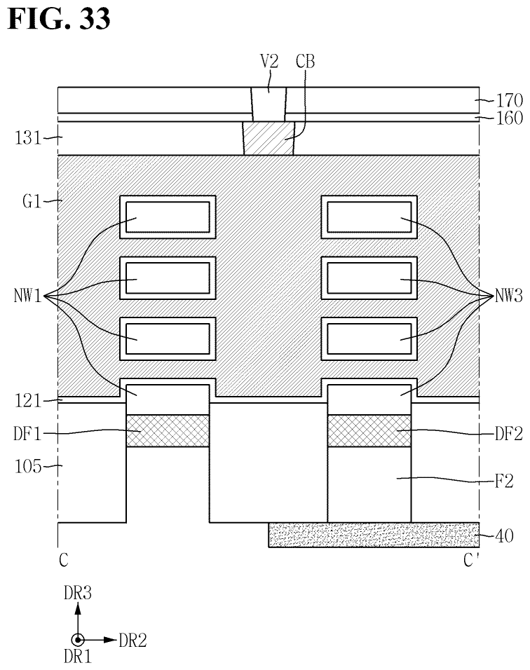

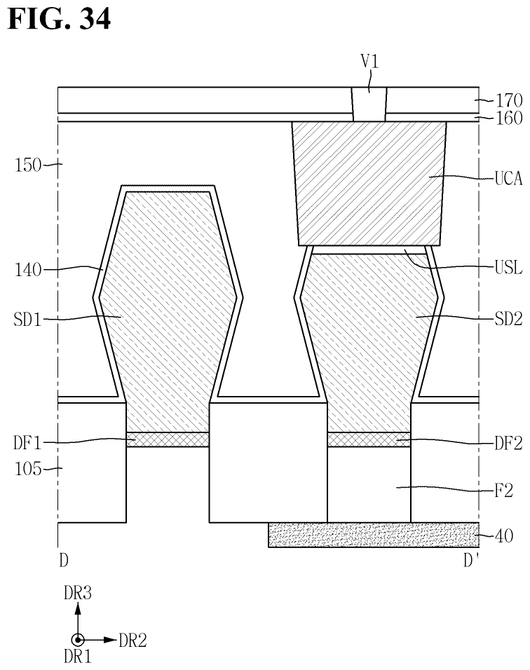

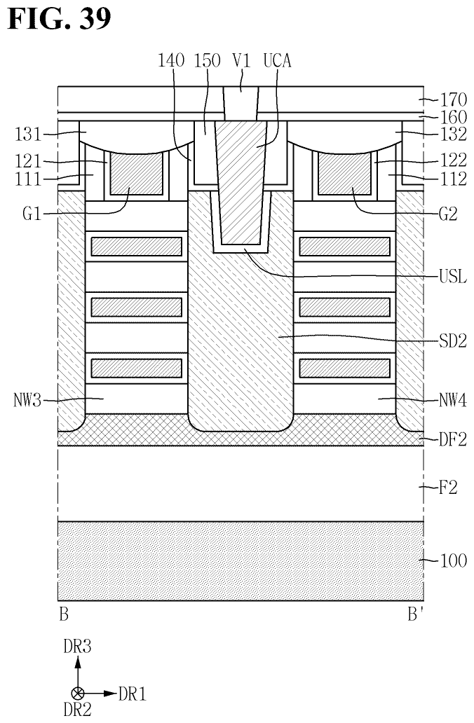

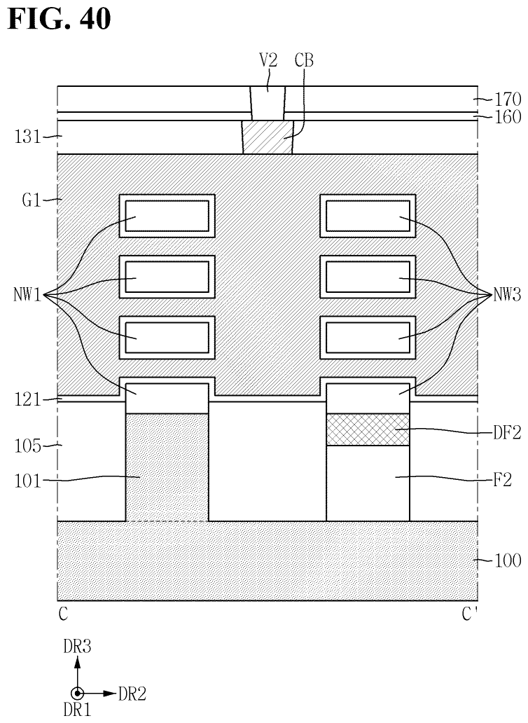

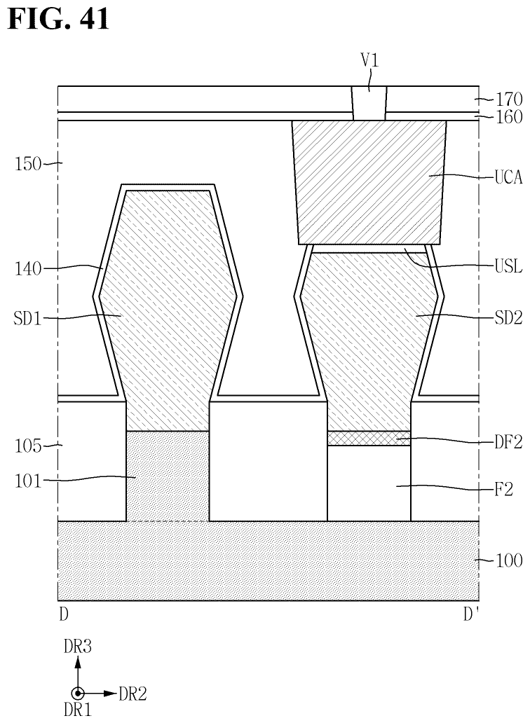

Hereinafter, with reference to FIGS. 2 to 41, a method of fabricating a semiconductor device according to some embodiments of the present disclosure will be described.

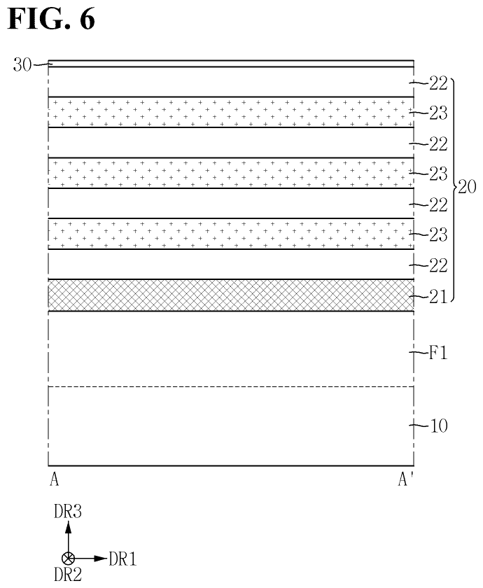

FIGS. 6 to 41 are intermediate stage diagrams for explaining the method of fabricating the semiconductor device according to some embodiments of the present disclosure.

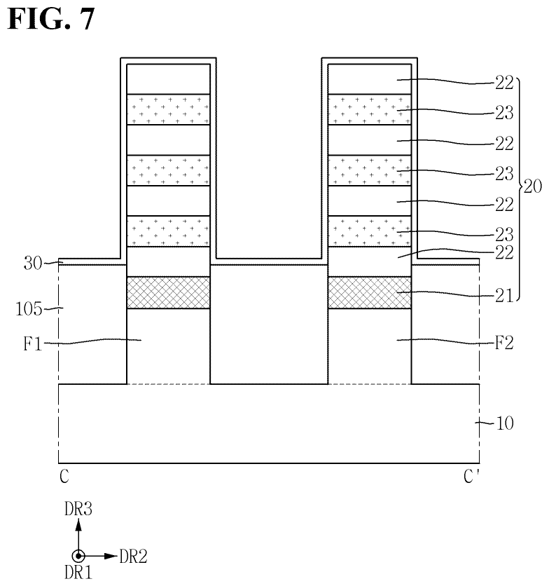

Referring to FIGS. 6 and 7, a substrate 10 may be provided. The substrate 10 may be a silicon substrate or SOI (silicon-on-insulator). In some other embodiments, the substrate 10 may include silicon germanium, SGOI (silicon germanium on insulator), indium antimonide, lead telluride compounds, indium arsenide, indium phosphide, gallium arsenide, or gallium antimonide, but the present disclosure is not limited thereto.

Subsequently, a laminated structure 20 may be formed on the upper surface of the substrate 10. For example, the laminated structure 20 may include a first semiconductor layer 21, a second semiconductor layer 22, and a third semiconductor layer 23. The first semiconductor layer 21 may be formed on the upper surface of the substrate 10. The first semiconductor layer 21 may be in contact with the upper surface of the substrate 10. For example, the first semiconductor layer 21 may include silicon germanium (SiGe). Subsequently, the second semiconductor layer 22 and the third semiconductor layer 23 may be alternately stacked on the upper surface of the first semiconductor layer 21. For example, a plurality of second semiconductor layers 22 and a plurality of third semiconductor layers 23 may be alternately stacked with one another on the upper surface of the first semiconductor layer 21. The lowermost second semiconductor layer 22 may be in contact with the upper surface of the first semiconductor layer 21. For example, the second semiconductor layer 22 may be formed on the top of the laminated structure 20. In other words, the uppermost second semiconductor layer 22 may be formed at the top of the laminated structure 20. For example, the second semiconductor layer 22 may include silicon (Si). For example, the third semiconductor layer 23 may include silicon germanium (SiGe). For example, the concentration of germanium (Ge) in the first semiconductor layer 21 may be higher than the concentration of germanium (Ge) in the third semiconductor layer 23. Here, the concentration of germanium (Ge) refers to the atomic ratio of germanium (Ge) contained in the silicon germanium (SiGe).

Subsequently, a portion of the laminated structure 20 may be etched. While the laminated structure 20 is being etched, a portion of the substrate 10 may also be etched. In other words, portions of the substrate 10 and the first to third semiconductor layers 21, 22, 23 may be etched. Through such etching processes, the first active pattern F1 and the second active pattern F2 may each be defined on the bottom of the laminated structure 20 on the upper surface of the substrate 10. Each of the first and second active patterns F1, F2 may protrude in the vertical direction DR3 from the upper surface of the substrate 10. Each of the first and second active patterns F1, F2 may extend in the first horizontal direction DR1. For example, each of the first and second active patterns F1, F2 may extend in the first horizontal direction DR1 on a lower surface of the first semiconductor layer 21. The second active pattern F2 may be spaced apart from the first active pattern F1 in the second horizontal direction DR2. For example, the profiles of the sidewalls in the second horizontal direction DR2 of each of the first and second active patterns F1, F2 may be formed continuously (e.g., in the vertical direction D3) with the profiles of the sidewalls in the second horizontal direction DR2 of the remaining laminated structure 20.

Then, the field insulating layer 105 may be formed on the upper surface of the substrate 10. The field insulating layer 105 may surround the sidewalls of the first active pattern F1, the sidewalls of the second active pattern F2, and the sidewalls of the first semiconductor layer 21, respectively. The field insulating layer 105 may be in contact with each of the sidewalls of the first active pattern F1, the sidewalls of the second active pattern F2, and the sidewalls of the first semiconductor layer 21. For example, the field insulating layer 105 may surround a portion of the sidewalls of the lowermost second semiconductor layer 22. The field insulating layer 105 may be in contact with a portion of the sidewalls of the bottom (i.e., lowermost) second semiconductor layer 22. For example, the upper surface of the field insulating layer 105 may be formed higher than the upper surface of the first semiconductor layer 21 (e.g., when measured relative to the upper surface of the substrate 10 in the vertical direction DR3). For example, the upper surface of the field insulating layer 105 may be formed higher than a bottom surface of the lowermost second semiconductor layer 22 (e.g., when measured relative to the upper surface of the substrate 10 in the vertical direction DR3). For example, the upper surface of the field insulating layer 105 may be formed lower than the upper surface of the lowermost second semiconductor layer 22 (e.g., when measured relative to the upper surface of the substrate 10 in the vertical direction DR3).

Subsequently, the pad oxide layer 30 may be formed to be on (e.g., to cover) the upper surface of the field insulating layer 105, the sidewalls and upper surface of exposed second semiconductor layer 22, and the sidewalls of exposed third semiconductor layer 23. For example, the pad oxide layer 30 may not be in contact with each of the first active pattern F1, the second active pattern F2, and the first semiconductor layer 21. For example, the pad oxide layer 30 may be formed conformally. The pad oxide layer 30 may include, for example, silicon oxide (SiO₂)

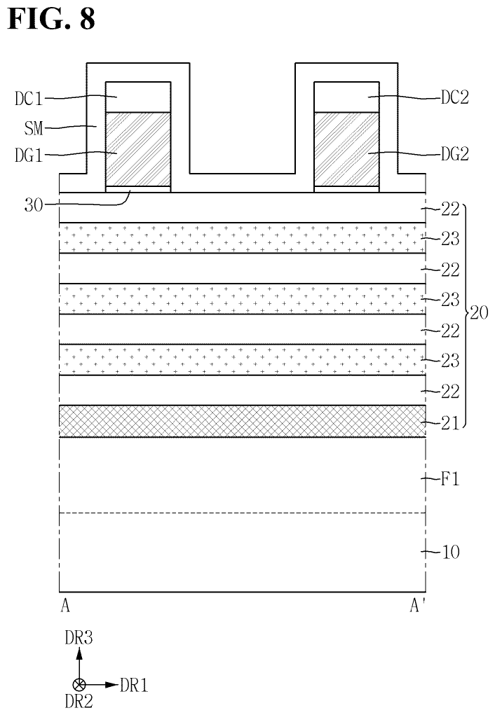

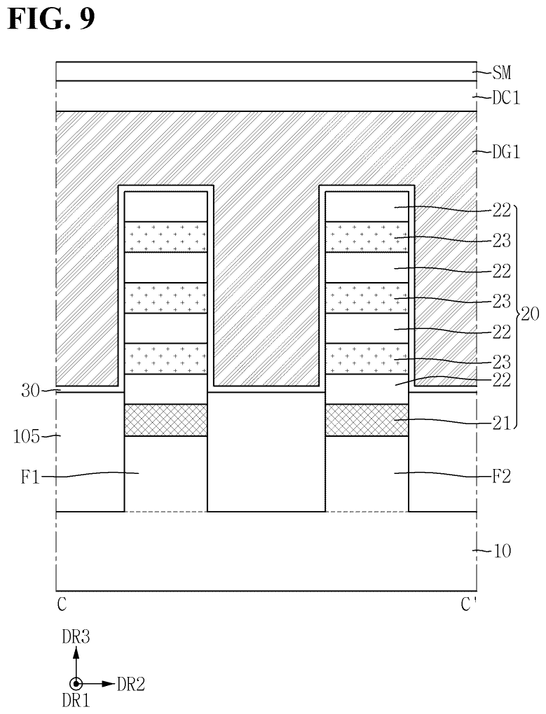

Referring to FIGS. 8 and 9, first and second dummy gates DG1, DG2 and first and second dummy capping patterns DC1, DC2 extending in the second horizontal direction DR2 on the pad oxide layer 30 on the laminated structure 20 and field insulating layer 105 may be formed. For example, the first and second dummy gates DG1, DG2 may be formed on an upper surface of the field insulating layer 105 and an upper surface of an uppermost second semiconductor layer 22. For example, the second dummy gate DG2 may be spaced apart from the first dummy gate DG1 in the first horizontal direction DR1. The first dummy capping pattern DC1 may be disposed on the first dummy gate DG1. The second dummy capping pattern DC2 may be disposed on the second dummy gate DG2. While the first and second dummy gates DG1, DG2 and the first and second dummy capping patterns DC1, DC2 are being formed, the remaining pad oxide layer 30 on the substrate 10 excluding the portions overlapping with the first and second dummy gates DG1, DG2 in the vertical direction DR3 may be removed.

Subsequently, the spacer material layer SM may be formed to be on (e.g., to cover) the sidewalls of each of the first and second dummy gates DG1, DG2, the sidewalls and upper surfaces of each of the first and second dummy capping patterns DC1, DC2, the sidewalls and upper surfaces of the exposed laminated structure 20, and the upper surface of the field insulating layer 105. For example, the spacer material layer SM may be formed conformally. The spacer material layer SM may include at least one of, for example, silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), or combinations thereof.

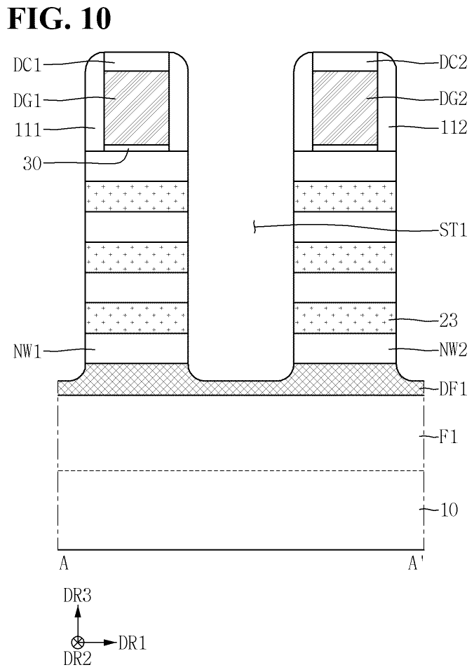

Referring to FIGS. 10 to 13, utilizing the first and second dummy gates DG1, DG2 and the first and second dummy capping patterns DC1, DC2 as masks, the laminated structure 20 (see FIGS. 8 and 9) may be etched to form the first and second source/drain trenches ST1, ST2. The first source/drain trench ST1 may be formed between the first dummy gate DG1 and the second dummy gate DG2 on the first active pattern F1. The second source/drain trench ST2 may be formed between the first dummy gate DG1 and the second dummy gate DG2 on the second active pattern F2.

For example, each of the first and second source/drain trenches ST1, ST2 may extend into an interior of the first semiconductor layer 21 (see FIGS. 8 and 9). In other words, the bottom surface of each of the first and second source/drain trenches ST1, ST2 may be defined by the first semiconductor layer 21 (see FIGS. 8 and 9). After the first source/drain trench ST1 is formed, the first semiconductor layer 21 (see FIGS. 8 and 9) remaining on the upper surface of the first active pattern F1 may be defined as the first dummy active pattern DF1. In other words, after the first source/drain trench ST1 is formed, a first portion of the first semiconductor layer 21 (see FIGS. 8 and 9) remaining on the upper surface of the first active pattern F1 may be defined as the first dummy active pattern DF1. Further, after the second source/drain trench ST2 is formed, the first semiconductor layer 21 (see FIGS. 8 and 9) remaining on the upper surface of the second active pattern F2 may be defined as the second dummy active pattern DF2. In other words, after the second source/drain trench ST2 is formed, a second portion of the first semiconductor layer 21 (see FIGS. 8 and 9) remaining on the upper surface of the second active pattern F2 may be defined as the second dummy active pattern DF2. That is, after the first and second source/drain trenches ST1, ST2 are formed respectively, each of the first and second dummy active patterns DF1, DF2 may be exposed. For example, the bottom surface of each of the first and second source/drain trenches ST1, ST2 may be formed lower than the upper surface of the field insulating layer 105 (e.g., when measured relative to the upper surface of the substrate 10 in the vertical direction DR3).

For example, while the first and second source/drain trenches ST1, ST2 are formed, the spacer material layer SM (see FIGS. 8 and 9) formed on the upper surface of each of the first and second dummy capping patterns DC1, DC2 and a portion of each of the first and second dummy capping patterns DC1, DC2 may be etched away. The spacer material layer SM (see FIGS. 8 and 9) remaining on the sidewalls of each of the first and second dummy capping patterns DC1, DC2 and the first and second dummy gates DG1, DG2 may be defined as the first and second gate spacers 111, 112.

For example, after the first source/drain trench ST1 is formed, the second semiconductor layers 22 (see FIGS. 8 and 9) remaining at the bottom of the first dummy gate DG1 on the first dummy active pattern DF1 may be defined as the first plurality of nanosheets NW1. After the first source/drain trench ST1 is formed, the second semiconductor layers 22 (see FIGS. 8 and 9) remaining at the bottom of the second dummy gate DG2 on the first dummy active pattern DF1 may be defined as the second plurality of nanosheets NW2. After the second source/drain trench ST2 is formed, the second semiconductor layers 22 (see FIGS. 8 and 9) remaining at the bottom of the first dummy gate DG1 on the second dummy active pattern DF2 may be defined as the third plurality of nanosheets NW3. After the second source/drain trench ST2 is formed, the second semiconductor layers 22 (see FIGS. 8 and 9) remaining at the bottom of the second dummy gate DG2 on the second dummy active pattern DF2 may be defined as the fourth plurality of nanosheets NW4.

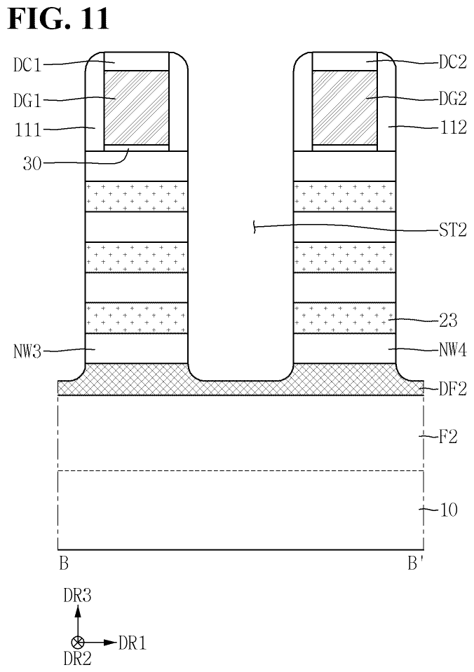

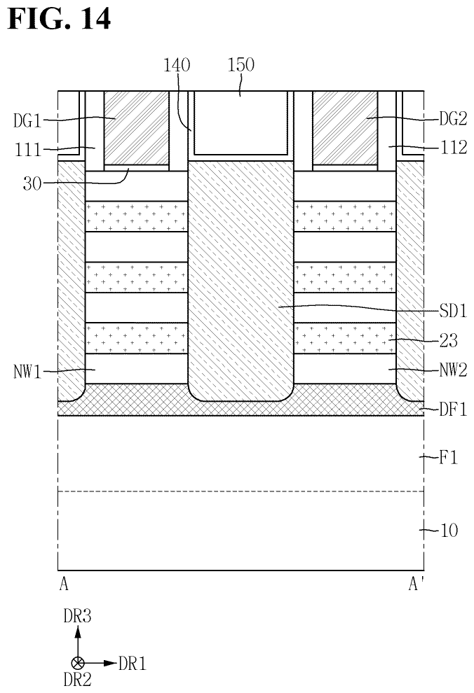

Referring to FIGS. 14 to 16, the first source/drain region SD1 may be formed inside of the first source/drain trench ST1 (see FIG. 10), and the second source/drain region SD2 may be formed inside of the second source/drain trench ST2 (see FIG. 11). For example, the lower surface of the first source/drain region SD1 may be in contact with the first dummy active pattern DF1. Further, the lower surface of the second source/drain region SD2 may be in contact with the second dummy active pattern DF2.

Subsequently, the first etch stop layer 140 may be formed on the upper surface of the exposed field insulating layer 105, the sidewalls of each of the exposed first and second gate spacers 111, 112, the upper surface of each of the exposed first and second dummy capping patterns DC1, DC2 (see FIGS. 10 and 11), and the surface of each of the exposed first and second source/drain regions SD1, SD2. Subsequently, the first upper interlayer insulating layer 150 may be formed on the first etch stop layer 140. Following this, a planarization process may be performed to expose the upper surface of each of the first and second dummy gates DG1, DG2.

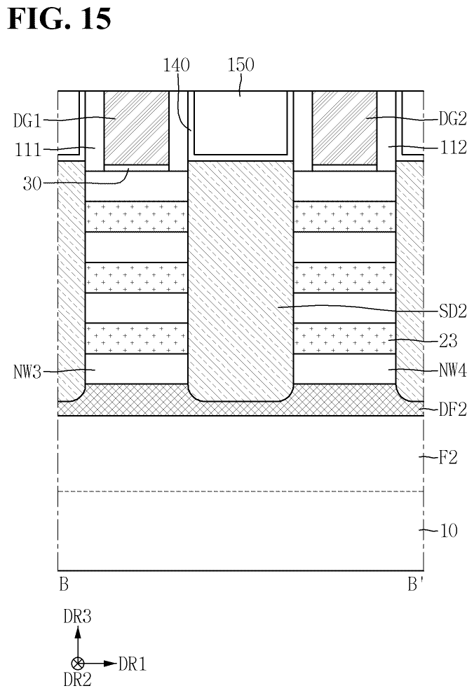

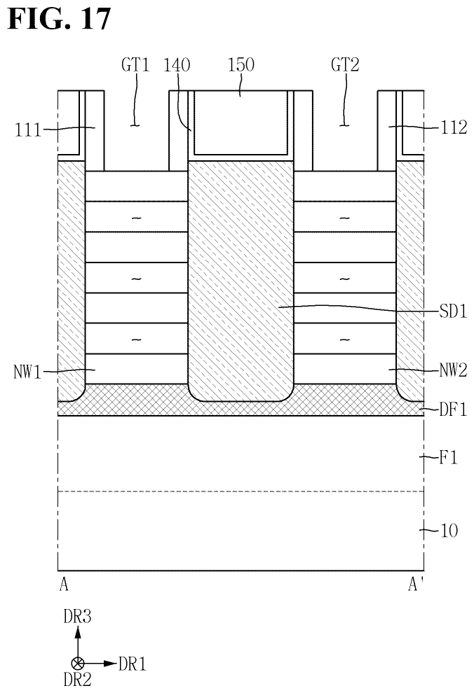

Referring to FIGS. 17 to 19, the first and second dummy gates DG1, DG2 (see FIGS. 14 and 15), the pad oxide layer 30 (see FIGS. 14 and 15), and the third semiconductor layers 23 (see FIGS. 14 and 15) may each be etched. The portions where the first dummy gate DG1 (see FIGS. 14 and 15), the pad oxide layer 30 (see FIGS. 14 and 15), and the third semiconductor layers 23 (see FIGS. 14 and 15) are etched may be defined as the first gate trench GT1. Further, the portions where the second dummy gate DG2 (see FIGS. 14 and 15), the pad oxide layer 30 (see FIGS. 14 and 15), and the third semiconductor layers 23 (see FIGS. 14 and 15) are etched may be defined as the second gate trench GT2.

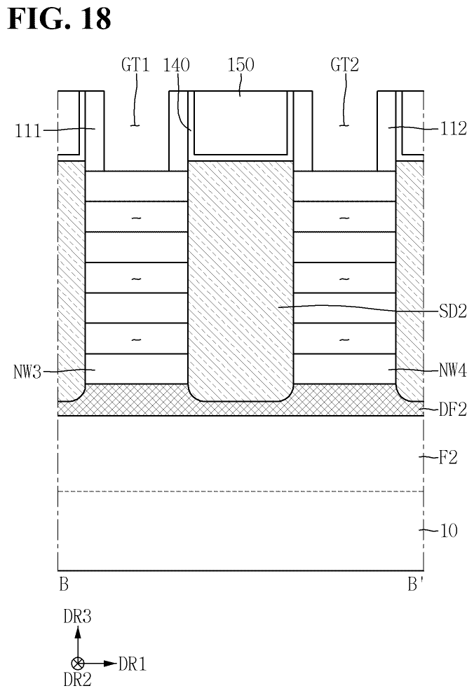

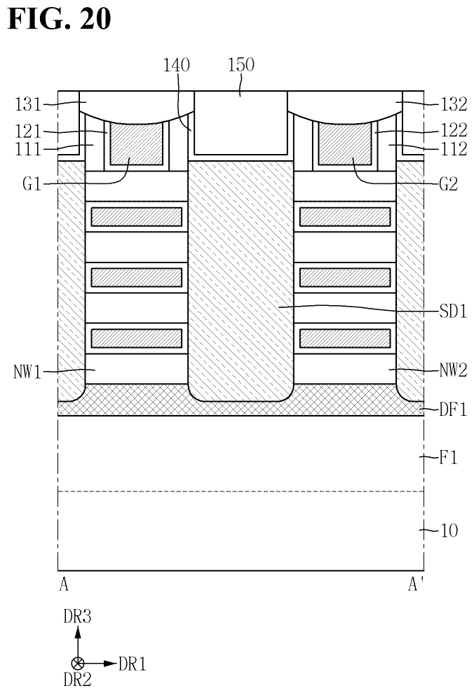

Referring to FIGS. 20 to 22, the first gate insulating layer 121, the first gate electrode G1, and the first capping pattern 131 may each be formed sequentially inside the first gate trench GT1 (see FIGS. 17 and 18). Further, the second gate insulating layer 122, the second gate electrode G2, and the second capping pattern 132 may each be formed sequentially inside the second gate trench GT2 (see FIGS. 17 and 18). For example, the first gate electrode G1 may surround each of the first and third plurality of nanosheets NW1, NW3. The second gate electrode G2 may surround each of the second and fourth plurality of nanosheets NW2, NW4.

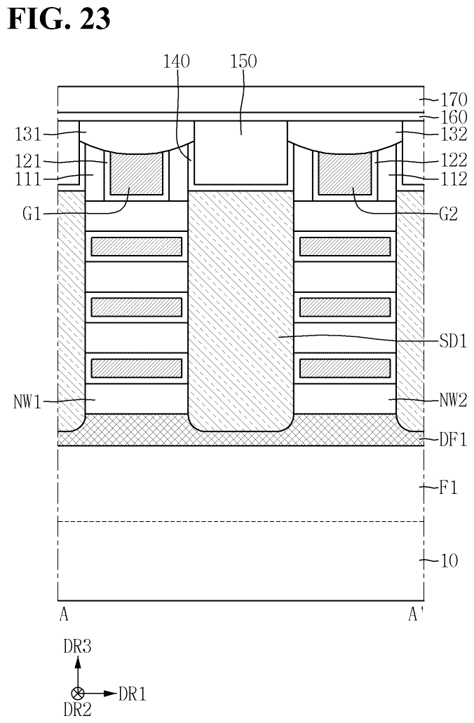

Referring to FIGS. 23 to 26, the upper source/drain contact UCA may be formed on the second source/drain region SD2. The upper source/drain contact UCA may extend into an interior of the second source/drain region SD2 by penetrating the first upper interlayer insulating layer 150 and the first etch stop layer 140 in the vertical direction DR3. Further, the upper silicide layer USL may be formed between the second source/drain region SD2 and the upper source/drain contact UCA. Furthermore, the gate contact CB connecting to the first gate electrode G1 may be formed by penetrating the first capping pattern 131 in the vertical direction DR3.

Subsequently, the second etch stop layer 160 and the second upper interlayer insulating layer 170 may be formed sequentially on the upper surface of each of the first upper interlayer insulating layer 150, the first and second capping patterns 131, 132, and the upper source/drain contact UCA. The first via V1 connecting to the upper source/drain contact UCA may be formed by penetrating the second etch stop layer 160 and the second upper interlayer insulating layer 170 in a vertical direction DR3. Additionally, the second via V2 connecting to the gate contact CB may be formed by penetrating the second etch stop layer 160 and the second upper interlayer insulating layer 170 in the vertical direction DR3.

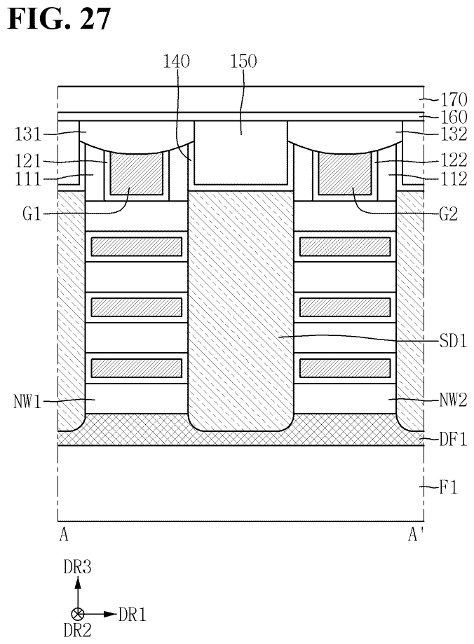

Referring to FIGS. 27 to 30, the substrate 10 (see FIGS. 23 to 26) may be etched. As a result, the lower surface of the field insulating layer 105, the lower surface of the first active pattern F1, and the lower surface of the second active pattern F2 may each be exposed. For example, the substrate 10 (see FIGS. 23 to 26) may be etched through a planarization process.

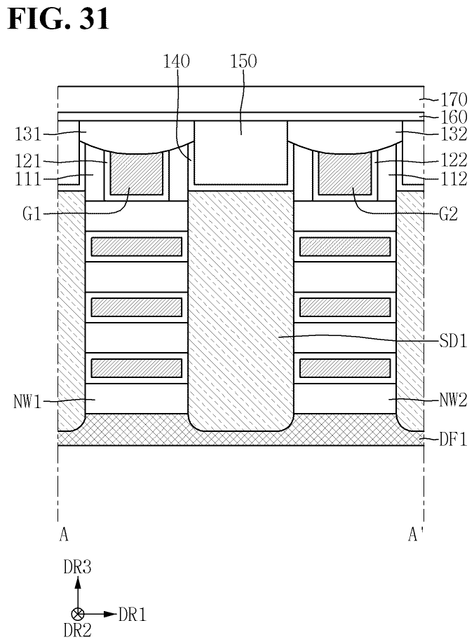

Referring to FIGS. 31 to 34, the protective layer 40 may be formed on the lower surface of the second active pattern F2. For example, the protective layer 40 may be formed on the lower surface of the field insulating layer 105 adjacent to the second active pattern F2. For example, the protective layer 40 is not formed on the lower surface of the first active pattern F1 (see FIGS. 27 to 30) and the lower surface of the field insulating layer 105 adjacent to the first active pattern F1 (see FIGS. 27 to 30). For example, the protective layer 40 may include a material different from the field insulating layer 105. For example, the protective layer 40 may include a material having etch selectivity with each of the first active pattern F1 (see FIGS. 27 to 30) and the first dummy active pattern DF1. For example, the protective layer 40 may include any one of silicon nitride (SiN), silicon carbonitride (SiCN), silicon oxynitride (SiON), or silicon oxycarbonitride (SiOCN), but the present disclosure is not limited thereto. Subsequently, the first active pattern F1 (see FIGS. 27 to 30) may be etched. As a result, the first dummy active pattern DF1 may be exposed.

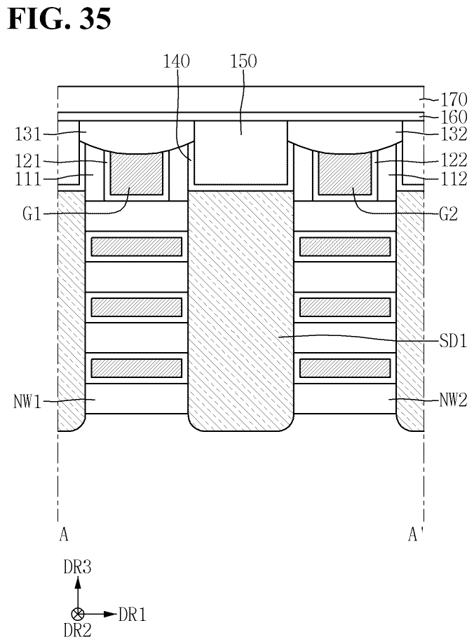

Referring to FIGS. 35 to 37, the first dummy active pattern DF1 (see FIGS. 31 to 34) may be etched. As a result, the lower surface of the lowermost nanosheet of the first plurality of nanosheets NW1, the lower surface of the lowermost nanosheet of the second plurality of nanosheets NW2, and the lower surface of the first source/drain region SD1 may be exposed, respectively.

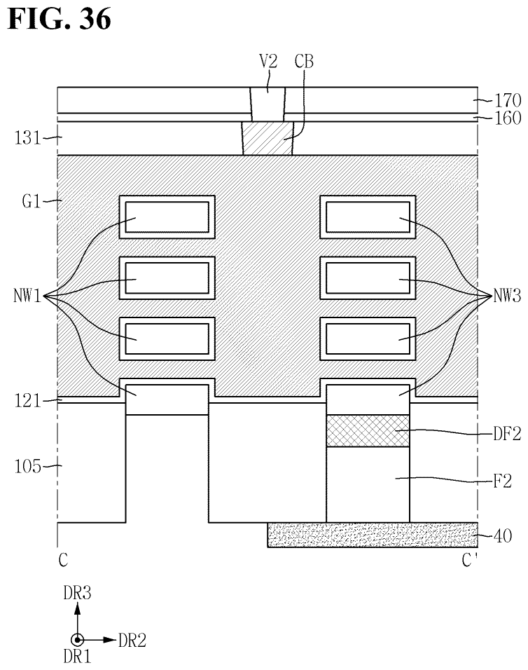

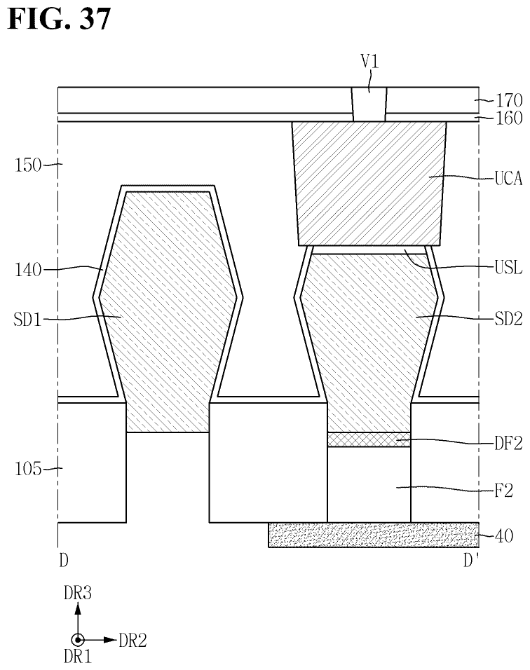

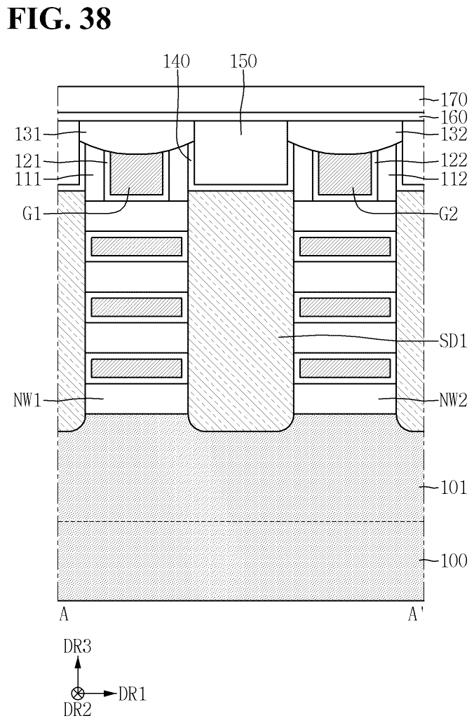

Referring to FIGS. 38 to 41, the protective layer 40 (see FIGS. 36 and 37) may be removed. Subsequently, the insulating pattern 101 may be formed on the portions where each of the first active pattern F1 (see FIGS. 27 to 30) and the first dummy active pattern DF1 (see FIGS. 31 to 34) is etched. For example, the insulating pattern 101 may be formed on a lower surface of the first source/drain region SD1. The insulating pattern 101 may extend in the first horizontal direction DR1. For example, the insulating pattern 101 may be in contact with the lower surface of the lowermost nanosheet of the first plurality of nanosheets NW1, the lower surface of the lowermost nanosheet of the second plurality of nanosheets NW2, and the lower surface of the first source/drain region SD1, respectively. Further, the sidewalls of the insulating pattern 101 may be in contact with the field insulating layer 105. For example, the uppermost surface of the insulating pattern 101 may be formed on the same plane as the uppermost surface of the second dummy active pattern DF2. For example, the lower surface of the insulating pattern 101 may be formed on the same plane as the lower surface of the second active pattern F2 and the lower surface of the field insulating layer 105.

Further, the lower interlayer insulating layer 100 may be formed on the lower surface of the insulating pattern 101, the lower surface of the second active pattern F2, and the lower surface of the field insulating layer 105, respectively. The lower interlayer insulating layer 100 may be in contact with the lower surface of the insulating pattern 101, the lower surface of the second active pattern F2, and the lower surface of the field insulating layer 105, respectively. For example, the lower interlayer insulating layer 100 may include the same material as the insulating pattern 101. For example, the insulating pattern 101 and the lower interlayer insulating layer 100 may be formed through the same fabricating process.

Referring to FIGS. 2 to 5, the bottom source/drain contact BCA may be formed by penetrating the lower interlayer insulating layer 100 and insulating pattern 101 in the vertical direction DR3 to be electrically connected to the first source/drain region SD1. For example, the sidewalls of the bottom source/drain contact BCA may be surrounded by the lower interlayer insulating layer 100 and the insulating pattern 101. For example, the upper surface of the bottom source/drain contact BCA may be formed on the same plane as the upper surface of the insulating pattern 101. However, the present disclosure is not limited thereto. In some other embodiments, at least a portion of the bottom source/drain contact BCA may extend into the interior of the first source/drain region SD1. Further, the bottom silicide layer BSL may be formed between the bottom source/drain contact BCA and the first source/drain region SD1. Through this fabrication process, the semiconductor device illustrated in FIGS. 2 to 5 may be fabricated.

The method of fabricating a semiconductor device according to some embodiments of the present disclosure may include forming first and second dummy active patterns DF1, DF2 on first and second active patterns F1, F2. In the process in which the first active pattern F1 including silicon (Si) is etched in the region where the bottom source/drain contact BCA is formed, the first dummy active pattern DF1 including silicon germanium (SiGe) may prevent the first source/drain region SD1 from being etched. As a result, the method of fabricating a semiconductor device according to some embodiments of the present disclosure may ensure the structural stability of the first source/drain region SD1 to which the bottom source/drain contact BCA is connected.

In the semiconductor device according to some embodiments of the present disclosure fabricated by the method described above, the insulating pattern 101 including an insulating material is disposed at the bottom of the first source/drain region SD1 to which the bottom source/drain contact BCA is connected, the second active pattern F2 including silicon (Si) and the second dummy active pattern DF2 including silicon germanium (SiGe) may be disposed at the bottom of the second source/drain region SD2 to which the upper source/drain contact UCA is connected. Further, the upper surface of the insulating pattern 101 and the second dummy active pattern DF2 may each be in contact with the lowermost nanosheet. Additionally, the upper surface of the field insulating layer 105 may be formed higher than each of the upper surface of the insulating pattern 101 and the upper surface of the second dummy active pattern DF2.

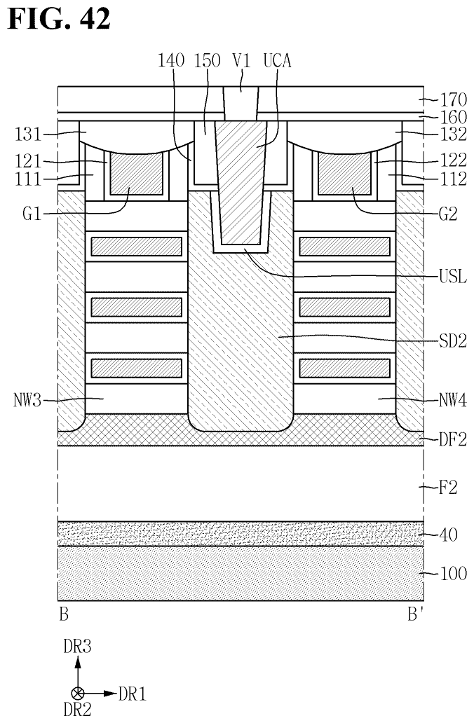

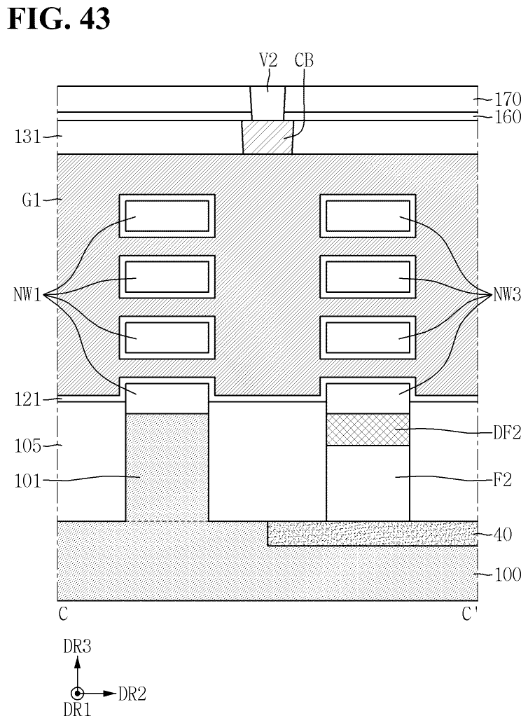

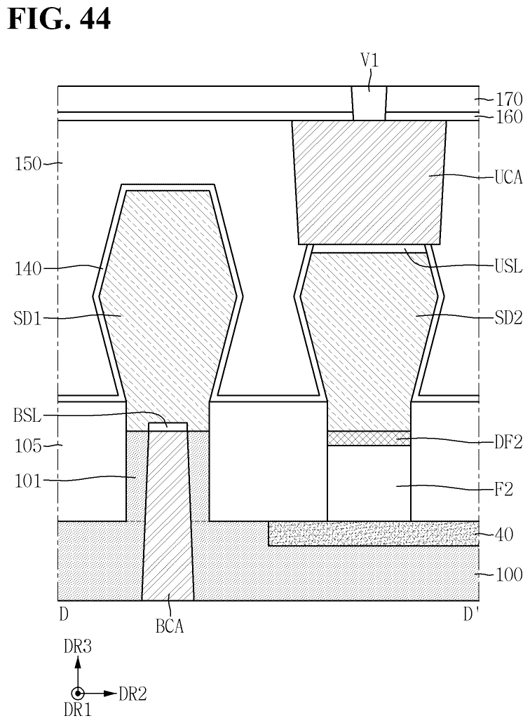

Hereinafter, a semiconductor device according to some other embodiments of the present disclosure will be described with reference to FIGS. 42 to 44. The description will focus on differences from the semiconductor device shown in FIGS. 1 to 5.

FIGS. 42 to 44 are cross-sectional views for explaining a semiconductor device according to some other embodiments of the present disclosure.

Referring to FIGS. 42 to 44, in the semiconductor device according to some other embodiments of the present disclosure, the protective layer 40 may be disposed on the lower surface of the second active pattern F2.

For example, the protective layer 40 may be disposed on the lower surface of the second active pattern F2 and the lower surface of the field insulating layer 105 adjacent to the second active pattern F2. The lower interlayer insulating layer 100 may be on (e.g., may cover) the protective layer 40 on the lower surface of the second active pattern F2 and the lower surface of the field insulating layer 105 adjacent to the second active pattern F2. That is, the protective layer 40 may be disposed between the lower interlayer insulating layer 100 and the lower surface of the second active pattern F2. Additionally, the protective layer 40 may be disposed between the lower interlayer insulating layer 100 and the lower surface of the field insulating layer 105.

For example, the protective layer 40 is not disposed on the lower surface of the insulating pattern 101. That is, the protective layer 40 may not be in contact with the lower surface of the insulating pattern 101. For example, the protective layer 40 may include a different material from each of the field insulating layer 105 and the lower interlayer insulating layer 100. Additionally, the protective layer 40 may include a different material from each of the second active pattern F2 and the second dummy active pattern DF2. For example, the protective layer 40 may include any one of silicon nitride (SiN), silicon carbonitride (SiCN), silicon oxynitride (SiON), or silicon oxycarbonitride (SiOCN), but the present disclosure is not limited thereto.

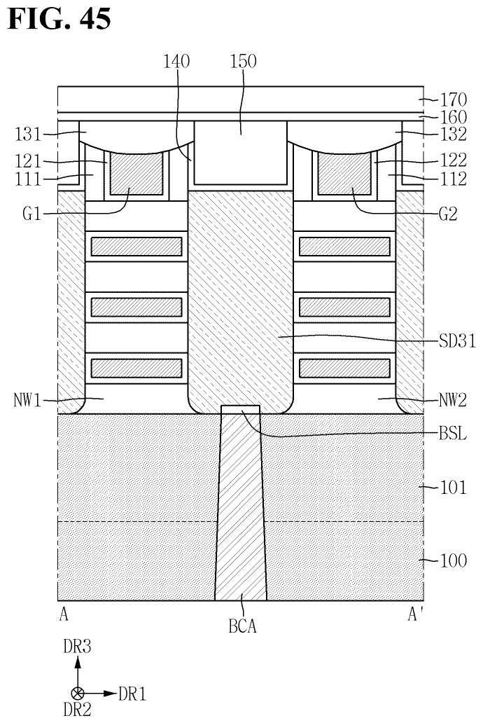

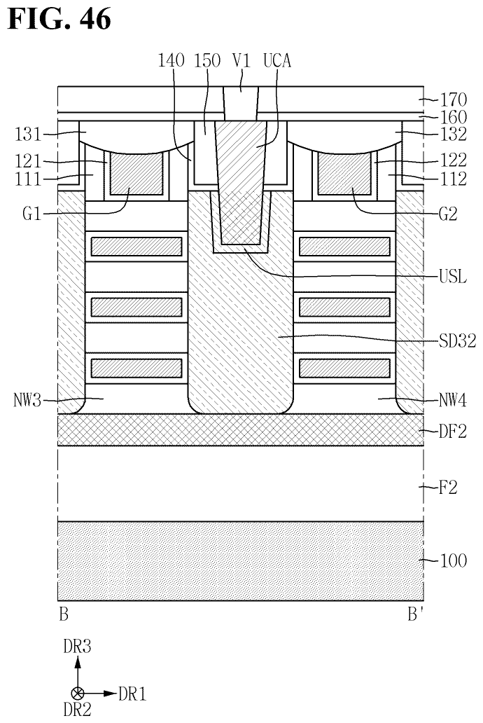

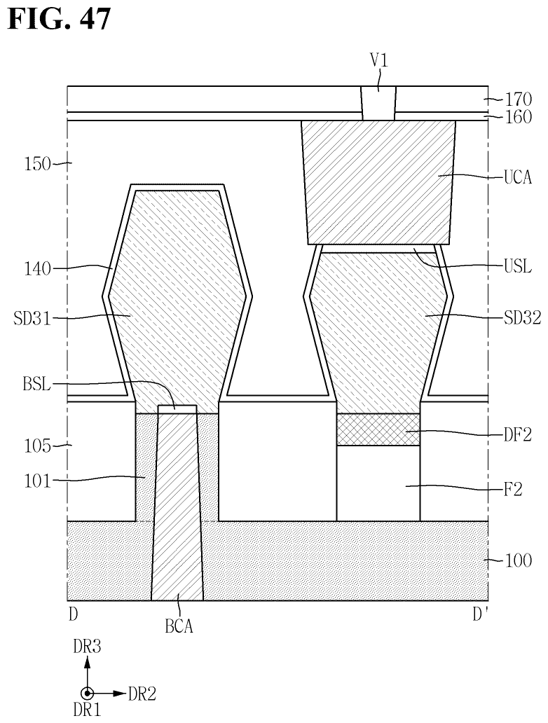

Hereinafter, with reference to FIGS. 45 to 47, a semiconductor device according to some other embodiments of the present disclosure will be described. The description will focus on differences from the semiconductor device illustrated in FIGS. 1 to 5.

FIGS. 45 to 47 are cross-sectional views for explaining a semiconductor device according to some other embodiments of the present disclosure.

Referring to FIGS. 45 to 47, in a semiconductor device according to some other embodiments of the present disclosure, the lower surface of each of the first and second source/drain regions SD31, SD32 may be formed on the same plane as the lower surface of the lowermost nanosheet.

For example, the lower surface of the first source/drain region SD31 may be formed on the same plane as each of the lower surface of the lowermost nanosheet of the first plurality of nanosheets NW1 and the lower surface of the lowermost nanosheet of the second plurality of nanosheets NW2. Additionally, the lower surface of the second source/drain region SD32 may be formed on the same plane as each of the lower surface of the lowermost nanosheet of the third plurality of nanosheets NW3 and the lower surface of the lowermost nanosheet of the fourth plurality of nanosheets NW4.

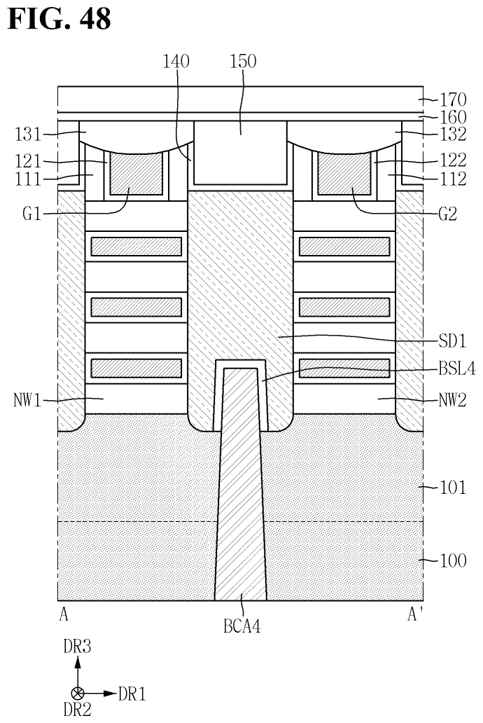

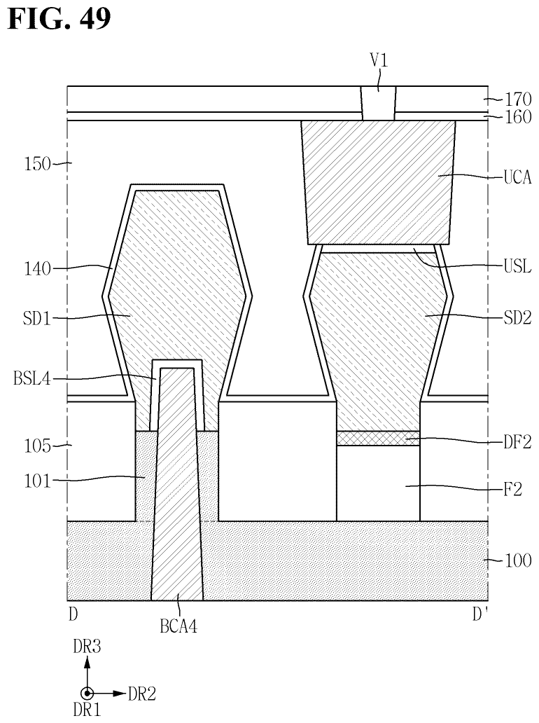

Hereinafter, with reference to FIGS. 48 and 49, a semiconductor device according to some other embodiments of the present disclosure will be described. The description will focus on differences from the semiconductor device illustrated in FIGS. 1 to 5.

FIGS. 48 and 49 are cross-sectional views for explaining a semiconductor device according to some other embodiments of the present disclosure.

Referring to FIGS. 48 and 49, in a semiconductor device according to some other embodiments of the present disclosure, at least a portion of the bottom source/drain contact BCA4 may extend into the interior of the first source/drain region SD1.

For example, the upper surface of the bottom source/drain contact BCA4 may be formed higher than the lower surface of the first source/drain region SD1 (e.g., when measured relative to the upper surface of the lower interlayer insulating layer 100 in the vertical direction DR3). For example, at least a portion of the bottom source/drain contact BCA4 may be surrounded by the first source/drain region SD1. At least a portion of the bottom source/drain contact BCA4 may overlap the first source/drain region SD1 in each of the first and second horizontal directions DR1, DR2. For example, the bottom silicide layer BSL4 may be disposed between the bottom source/drain contact BCA4 and the first source/drain region SD1. The bottom silicide layer BSL4 may be disposed along the interface between the bottom source/drain contact BCA4 and the first source/drain region SD1.

While example embodiments according to the present disclosure have been described above with reference to the accompanying drawings, it will be understood that the present disclosure is not limited to the above embodiments and may be fabricated in a variety of different forms, and those skilled in the art to which the present disclosure belongs, with ordinary knowledge in the field, may recognize that it may be implemented in other specific forms without changing the technical idea or essential features of the present disclosure. Therefore, it should be understood that the above-described embodiments are examples in all respects and not restrictive.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor device comprising:
a lower interlayer insulating layer;
an insulating pattern extending in a first horizontal direction on an upper surface of the lower interlayer insulating layer;
an active pattern extending in the first horizontal direction on the upper surface of the lower interlayer insulating layer, the active pattern spaced apart from the insulating pattern in a second horizontal direction different from the first horizontal direction, the active pattern including a material different from a material of the insulating pattern;
a dummy active pattern extending in the first horizontal direction on an upper surface of the active pattern and in contact with the upper surface of the active pattern;
a field insulating layer on the upper surface of the lower interlayer insulating layer and on sidewalls of the insulating pattern, the active pattern, and the dummy active pattern;
a first plurality of nanosheets stacked and spaced apart from each other in a vertical direction on an upper surface of the insulating pattern;
a second plurality of nanosheets stacked and spaced apart from each other in the vertical direction on an upper surface of the dummy active pattern;
a gate electrode extending in the second horizontal direction on the insulating pattern and the dummy active pattern, the gate electrode at least partially surrounding each of the first and second plurality of nanosheets;
a first source/drain region on a side of the gate electrode and on the insulating pattern, the first source/drain region being in contact with the insulating pattern;
a second source/drain region on the side of the gate electrode and on the dummy active pattern, the second source/drain region being in contact with the dummy active pattern;
a bottom source/drain contact extending in the lower interlayer insulating layer and the insulating pattern in the vertical direction, the bottom source/drain contact electrically connected to the first source/drain region; and
an upper source/drain contact on the second source/drain region, the upper source/drain contact electrically connected to the second source/drain region.

2. The semiconductor device of claim 1, wherein the dummy active pattern includes silicon germanium (SiGe).

3. The semiconductor device of claim 1, wherein an uppermost surface of the insulating pattern is coplanar with an uppermost surface of the dummy active pattern.

4. The semiconductor device of claim 1, wherein an upper surface of the field insulating layer is higher in the vertical direction than the upper surface of the insulating pattern and the upper surface of the dummy active pattern, relative to the upper surface of the lower interlayer insulating layer.

5. The semiconductor device of claim 1, wherein a lower surface of a lowermost nanosheet of the first plurality of nanosheets is in contact with the upper surface of the insulating pattern, and
wherein a lower surface of a lowermost nanosheet of the second plurality of nanosheets is in contact with the upper surface of the dummy active pattern.

6. The semiconductor device of claim 1, wherein the field insulating layer is in contact with opposing sidewalls in the second horizontal direction of a lowermost nanosheet of the first plurality of nanosheets and opposing sidewalls in the second horizontal direction of a lowermost nanosheet of the second plurality of nanosheets.

7. The semiconductor device of claim 1, wherein the insulating pattern overlaps the dummy active pattern in the second horizontal direction.

8. The semiconductor device of claim 1, wherein a lower surface of the insulating pattern and a lower surface of the active pattern are in contact with the lower interlayer insulating layer.

9. The semiconductor device of claim 1, further comprising a protective layer between the lower interlayer insulating layer and a lower surface of the active pattern, the protective layer including a material different from a material of the lower interlayer insulating layer,
wherein a lower surface of the insulating pattern is in contact with the lower interlayer insulating layer.

10. The semiconductor device of claim 1, wherein a lower surface of the first source/drain region is coplanar with a lower surface of a lowermost nanosheet of the first plurality of nanosheets, and
wherein a lower surface of the second source/drain region is coplanar with a lower surface of a lowermost nanosheet of the second plurality of nanosheets.

11. The semiconductor device of claim 1, wherein at least a portion of the bottom source/drain contact extends into the first source/drain region.

12. A semiconductor device comprising:
a lower interlayer insulating layer;
an insulating pattern extending in a first horizontal direction on an upper surface of the lower interlayer insulating layer,
an active pattern extending in the first horizontal direction on the upper surface of the lower interlayer insulating layer, the active pattern spaced apart from the insulating pattern in a second horizontal direction different from the first horizontal direction, the active pattern including a material different from a material of the insulating pattern;
a dummy active pattern extending in the first horizontal direction on an upper surface of the active pattern and in contact with the upper surface of the active pattern, the dummy active pattern including silicon germanium (SiGe);
a field insulating layer on the upper surface of the lower interlayer insulating layer and on sidewalls of the insulating pattern, the active pattern, and the dummy active pattern, wherein an upper surface of the field insulating layer is higher in a vertical direction than an upper surface of the insulating pattern and an upper surface of the dummy active pattern, relative to the upper surface of the lower interlayer insulating layer;
a gate electrode extending in the second horizontal direction on the insulating pattern and the dummy active pattern;
a first source/drain region on a side of the gate electrode and on the insulating pattern;
a second source/drain region on the side of the gate electrode and on the dummy active pattern,
a bottom source/drain contact extending in the lower interlayer insulating layer and the insulating pattern in the vertical direction, the bottom source/drain contact electrically connected to the first source/drain region; and
an upper source/drain contact on the second source/drain region, the upper source/drain contact electrically connected to the second source/drain region.

13. The semiconductor device of claim 12, further comprising:
a first plurality of nanosheets stacked and spaced apart from each other in the vertical direction on the upper surface of the insulating pattern; and
a second plurality of nanosheets stacked and spaced apart from each other in the vertical direction on the upper surface of the dummy active pattern,
wherein the gate electrode at least partially surrounds each of the first and second plurality of nanosheets.

14. The semiconductor device of claim 12, wherein a lower surface of the first source/drain region is in contact with the insulating pattern, and
wherein a lower surface of the second source/drain region is in contact with the dummy active pattern.

15. The semiconductor device of claim 12, wherein the insulating pattern overlaps the dummy active pattern in the second horizontal direction.

16. A method of fabricating a semiconductor device comprising:
forming a first semiconductor layer including silicon germanium (SiGe) on an upper surface of a substrate;
alternately stacking second semiconductor layers including silicon (Si) and third semiconductor layers including silicon germanium (SiGe) on an upper surface of the first semiconductor layer;
etching portions of the substrate and the first to third semiconductor layers to form first and second active patterns extending in a first horizontal direction on a lower surface of the first semiconductor layer, wherein the second active pattern is spaced apart from the first active pattern in a second horizontal direction different from the first horizontal direction;
forming a field insulating layer on the substrate and on sidewalls of the first active pattern, the second active pattern, and the first semiconductor layer;
forming a dummy gate extending in the second horizontal direction on an upper surface of the field insulating layer and on an upper surface of an uppermost one of the second semiconductor layers;
forming a first source/drain region on a side of the dummy gate and on the first active pattern, and forming a second source/drain region on the side of the dummy gate and on the second active pattern, wherein a first portion of the first semiconductor layer in contact with a lower surface of the first source/drain region is defined as a first dummy active pattern, and wherein a second portion of the first semiconductor layer in contact with a lower surface of the second source/drain region is defined as a second dummy active pattern,
etching the dummy gate and the third semiconductor layers to form a gate trench;
forming a gate electrode in the gate trench;
forming an upper source/drain contact on the second source/drain region and electrically connected to the second source/drain region;
etching the substrate, forming a protective layer on a lower surface of the second active pattern;
etching the first active pattern and the first dummy active pattern;
forming an insulating pattern on the lower surface of the first source/drain region, the insulating pattern extending in the first horizontal direction; and
forming a bottom source/drain contact extending in the insulating pattern in a vertical direction and electrically connected to the first source/drain region.

17. The method of claim 16, wherein a concentration of germanium (Ge) included in the first semiconductor layer is greater than a concentration of germanium (Ge) included in each of the third semiconductor layers.

18. The method of claim 16, wherein forming the field insulating layer comprises forming the upper surface of the field insulating layer higher in the vertical direction than the upper surface of the first semiconductor layer, relative to the upper surface of the substrate.

19. The method of claim 16, wherein forming the insulating pattern comprises forming an uppermost surface of the insulating pattern coplanar with an uppermost surface of the second dummy active pattern.

20. The method of claim 16, further comprising removing the protective layer after etching the first active pattern and the first dummy active pattern.
